(19) United States
(12) Patent Application Publication
(10) Pub. No.: US 2017/0288062 A1
(43) Pub. Date: Oct. 5, 2017

(54) SEMICONDUCTOR DEVICE AND METHOD OF PRODUCING SEMICONDUCTOR DEVICE

(71) Applicant: Sharp Kabushiki Kaisha, Sakai City, Osaka (JP)

(72) Inventors: Takao SAITOH, Sakai City (JP); Seiji KANEKO, Sakai City (JP); Yohsuke KANZAKI, Sakai City (JP); Yutaka TAKAMARU, Sakai City (JP); Keisuke IDE, Sakai City (JP); Takuya MATSUO, Sakai City (JP)

(73) Assignee: Sharp Kabushiki Kaisha, Sakai City, Osaka (JP)

(21) Appl. No.: 15/507,780

(22) PCT Filed: Aug. 26, 2015
(86) PCT No.: PCT/JP2015/073948

§ 371 Date: Mar. 1, 2017

(30) Foreign Application Priority Data
Sep. 2, 2014 (JP) 2014-178219

(51) Int. Cl. H01L 29/786; H01L 29/66; H01L 27/12; H01L 29/24

(52) U.S. Cl. CPC H01L 29/7869; H01L 29/24; H01L 29/66969; H01L 27/1225; H01L 27/127

(57) ABSTRACT

A semiconductor device includes an oxide semiconductor film, a first insulating film, and a second insulating film. The oxide semiconductor film is made of oxide semiconductor material. The oxide semiconductor film includes a low resistance portion having an electrical resistance lower than another portion. The low resistance portion is separated from the other portion. The first insulating film is formed in an upper layer relative to the oxide semiconductor film. The first insulating film includes a hole at a position overlapping the low resistance portion. The second insulating film is formed in an upper layer relative to the first insulating film. The second insulating film and contains hydrogen.

### TECHNICAL FIELD

The present invention relates to a semiconductor device and a method of producing the semiconductor device.

### BACKGROUND ART

Examples of known methods of producing semiconductor devices include a method disclosed in Patent Document 1. Patent Document 1 discloses the method including a first step, a second step, a third step, a fourth step, a fifth step, and a sixth step. The first step is for forming gate electrodes on a substrate. The second step is for forming a first insulating layer on the gate electrodes, forming an oxide semiconductor layer on the first insulating layer from an oxide semiconductor, and forming an electrode layer on the oxide semiconductor layer. The third step is for forming a photoresist on the electrode layer, exposing the photoresist to light using a halftone mask, developing the photoresist to form a resist pattern including a first portion having a larger thickness and a second portion having a smaller thickness, and etching the electrode layer and the oxide semiconductor layer using the resist pattern as a photomask. The fourth step is for removing the second portion of the resist pattern to form a non-covered portion and etching the electrode layer using the first portion of the resist pattern as a mask. The fifth step is for forming a second insulating layer and patterning the second insulating layer. The sixth step is for reducing a resistance of the oxide semiconductor layer in the non-covered portion.

### RELATED ART DOCUMENT

### Patent Document

Patent Document 1: Japanese Unexamined Patent Application Publication No. 2011-91279

### Problem to be Solved by the Invention

The method of producing the semiconductor device disclosed in Patent Document 1 includes a special treatment for reducing the resistance of the oxide semiconductor layer such as a hydrogen plasma treatment. Therefore, a facility for the treatment is required. This may increase a production cost or cause problems.

### DISCLOSURE OF THE PRESENT INVENTION

The present invention was made in view of the above circumstances. An object is to reduce a resistance of an oxide semiconductor film at low cost.

### Means for Solving the Problem

A semiconductor device includes an oxide semiconductor film, a first insulating film, and a second insulating film. The oxide semiconductor film is made of oxide semiconductor material. The oxide semiconductor film includes a low resistance portion having an electrical resistance lower than an electrical resistance of another portion. The lower resistance portion is separated from the other portion. The first insulating film is formed in an upper layer relative to the oxide semiconductor film. The first insulating film includes a hole at a position overlapping the low resistance portion. The second insulating film is formed in an upper layer relative to the first insulating film. The second insulating film contains hydrogen.

According to the configuration, a portion of the second insulating film is directly layered on a portion of the oxide semiconductor film facing the hole in the first insulating film via the hole. Therefore, the hydrogen contained in the second insulating film is diffused into the portion of the oxide semiconductor film facing the hole and the electrical resistance of the portion of the oxide semiconductor film is reduced. Because the resistance of the portion of the oxide semiconductor film is reduced using the second insulating film, the special treatment such as a hydrogen plasma treatment included in the known method is not required. Therefore, the production can be performed at low cost. If the low resistance portion and the other portion of the oxide semiconductor film are connected to each other, the hydrogen diffused from the second insulating film to the low resistance portion may be diffused into the other portion. As described above, the low resistance portion is separated from the other portion. Therefore, the hydrogen diffused from the second insulating film into the low resistance portion is less likely to affect the other portion. According to the configuration, the electrical resistances of the low resistance portion and the other portion are properly maintained and thus the low resistance portion and the other portion properly exert the electrical performances.

Preferable embodiments of the semiconductor device according to the present invention may include the following configurations.

(1) The semiconductor device may further include a pixel electrode and a capacitive trace. The pixel electrode may be formed from a transparent electrode film in an upper layer relative to the second insulating film. The capacitive trace may be formed in a lower layer relative to the first insulating film to overlap the pixel electrode. The oxide semiconductor film may be formed such that the capacitive trace is formed from the low resistance portion. Because the capacitive trace is arranged to overlap the pixel electrode, capacitance is produced between the pixel electrode and the capacitive trace. Therefore, the electrical potential at the pixel electrode is maintained. The capacitive trace is formed from the low resistance portion of the oxide semiconductor film separated from the other portion of the oxide semiconductor film. Therefore, a sufficient capacitance is produced between the pixel electrode and the capacitive trace. In comparison to a configuration in which the capacitive trace is formed from a light blocking film such as a metal film, light is less likely to be blocked by the capacitive trace. According to the configuration, an amount of transmitting light through the pixel electrode formed from the transparent electrode film can be increased.

(2) The semiconductor device may further include a pixel electrode and a transistor. The pixel electrode may be formed from a transparent electrode film in an upper layer relative to the second insulating film. The transistor may be formed in a lower layer relative to the pixel electrode and connected to the pixel electrode to control application of an electrical potential to the pixel electrode. The oxide semiconductor film may be formed such that a channel included in the transistor is formed from the other portion. The application of the electrical potential to the pixel electrode is controlled by the transistor. Because the channel of the transistor is formed from the other portion of the oxide semiconductor film separated from the low resistance portion, the transistor is properly operable.

(3) The second insulating film may include a lower second insulating film formed in a lower layer and an upper second insulating film formed in an upper layer. If the forming temperature of the second insulating film is too low, the hydrogen may not be sufficiently diffused to the portion of the oxide semiconductor film. Therefore, the resistance of the portion of the oxide semiconductor film may not be sufficiently reduced. If the forming temperature of the second insulating film is too high, the elements contained in the oxide semiconductor film are diffused into the second insulating film. Therefore, the bumps and the dips are more likely to be formed on and in the second insulating film. As described above, the second insulating film may have a laminated structure including the lower second insulating film and the upper second insulating film. Therefore, the forming temperature of the lower second insulating film may be set to a lower temperature and the forming temperature of the upper second insulating film may be set to a higher temperature. Even if the resistance of the oxide semiconductor film is not sufficiently reduced at the completion of the formation of the lower second insulating film, the bumps and the dips are less likely to be formed on and in the surface of the lower second insulating film. By forming the upper second interlayer insulating film at the higher forming temperature, the hydrogen is efficiently diffused from the lower second insulating film into the oxide semiconductor film under the temperature environment. Therefore, the resistance is reduced. Because the lower second insulating film is provided between the oxide semiconductor film and the upper second insulating film, the bumps and the dips are less likely to be formed on and in the surface of the upper second insulating film.

A method of producing a semiconductor device according to the present invention includes an oxide semiconductor film forming step, a first insulating film forming step, a hole forming step, and a second insulating film forming step. The oxide semiconductor film is for forming an oxide semiconductor film from oxide semiconductor material to separate a portion of the oxide semiconductor film from another portion of the oxide semiconductor film. The first insulating film forming step is for forming a first insulating film in an upper layer relative to the oxide semiconductor film. The hole forming step is for forming a hole in the first insulating film at a position overlapping the portion of the oxide semiconductor film. The second insulating film forming step is for forming a second insulating film containing hydrogen in an upper layer relative to the first insulating film.

Through the oxide semiconductor film forming step and the first insulating film forming step, the first insulating film is formed in the upper layer relative to the oxide semiconductor film that includes the portion and the other portion separated from each other. In the hole forming step, the hole is formed in the first insulating film at the position overlapping the portion of the oxide semiconductor film. When the second insulating film is formed in the upper layer relative to the first insulating film in the second insulating film forming step performed after the hole forming step, a portion of the second insulating film is directly layered on a portion of the oxide semiconductor film facing the hole in the first insulating film. The hydrogen contained in the second insulating film is diffused into the portion of the oxide semiconductor film facing the hole. Therefore, the electrical resistance is reduced. Because the resistance of the portion of the oxide semiconductor film is reduced using the second insulating film, the special treatment such as a hydrogen plasma treatment included in the known method is not required and thus the production can be performed at low cost. If the portion of the oxide semiconductor film having a lowered resistance and the other portion of the oxide semiconductor film are connected to each other, the hydrogen diffused from the second insulating film to the portion of the oxide semiconductor film may be diffused to the other portion of the oxide semiconductor film. As described above, the portion of the oxide semiconductor film is separated from the other portion of the oxide semiconductor film. Therefore, the hydrogen diffused from the second insulating film into the portion of the oxide semiconductor film is less likely to affect the other portion of the oxide semiconductor film. Because the electrical resistances of the portion and the other portion of the oxide semiconductor film are maintained at proper levels, the portion and the other portion of the oxide semiconductor film properly exert the electrical performances.

Preferable embodiments of the method of producing the semiconductor device according to the present invention may include the following features.

(1) The second insulating film forming step may include forming the second insulating film at a forming temperature in a range from 220° C. to 270° C. If the forming temperature of the second insulating film is below 220° C., the hydrogen may not be sufficiently diffused into the portion of the oxide semiconductor film. Therefore, the resistance of the portion of the oxide semiconductor film may not be sufficiently reduced. If the forming temperature of the second insulting film is above 270° C., the elements contained in the oxide semiconductor film may be diffused into the second insulting film. Therefore, the bumps and the dips may be formed on and in the surface of the second insulating film. As described above, the forming temperature of the second insulating film may be in the range from 220° C. to 270° C. in the second insulating film forming step. Therefore, the hydrogen may be sufficiently diffused into the portion of the oxide semiconductor film and the resistance of the portion of the oxide semiconductor film is sufficiently reduced. Furthermore, the elements contained in the oxide semiconductor film are less likely to be diffused into the second insulating film. Therefore, the bumps and the dips are less likely to be formed on and in the surface of the second insulating film.

(2) The method may include an annealing treatment step for performing an annealing treatment at a temperature in a range from 220° C. to 350° C. after the second insulating film forming step. The second insulating film forming step may include forming the second insulating film at a forming temperature in a range from 150° C. to 220° C. If the second insulating film is formed at a temperature lower than 220° C. in the second insulating film forming step, the elements contained in the oxide semiconductor film are less likely to be diffused into the second insulating film. The bumps and the dips are more likely to be formed on and in the surface of the second insulating film. The hydrogen is not sufficiently diffused to the portion of the oxide semiconductor film. Therefore, the resistance of the portion of the oxide semiconductor film may not be sufficiently reduced. With the annealing treatment performed at 220° C. or higher in the annealing treatment step performed after the second insulating film forming step, the hydrogen is sufficiently diffused into the portion of the oxide semiconductor film. Therefore, the resistance of the portion of the oxide semiconductor film is sufficiently reduced. If the second insulating film is formed at the forming temperature of 150° C. or lower in the second insulating film forming step or the annealing treatment is performed at 350° C. or higher in the annealing treatment step, the semiconductor device may not properly exert the electrical performances. As described above, the forming temperature of the second insulating film is 150° C. or higher in the second insulating film forming step and the temperature of the annealing treatment is 350° C. or lower in the annealing treatment step. Therefore, the semiconductor device can exert the electrical performances.

(3) The annealing treatment step may include performing the annealing treatment at a temperature in a range from 270° C. to 350° C. The resistance of the portion of the oxide semiconductor film may be more properly reduced. The bumps and the dips may be formed on and in the surface of the second insulating film when the second insulating film is formed in the upper layer relative to the first insulating film. Therefore, although the annealing treatment is performed at the temperature in the range from 270° C. to 350° C., the bumps and the dips are less likely to be newly formed on and in the surface of the second insulating film.

(4) The second insulating film forming step may include a lower second insulating film forming step and an upper second insulating film forming step. The lower second insulating film forming step is for forming a lower second insulating film in a lower layer at a lower forming temperature. The upper second insulating film forming step is for forming an upper second insulating film in an upper layer at a higher forming temperature. Because the lower second insulating film is formed at the lower forming temperature in the lower second insulating film forming step, the bumps and the dips are less likely to be formed on and in the surface of the lower second insulting film even through the resistance of the oxide semiconductor film is not sufficiently reduced. The upper second insulating film if formed at the high forming temperature in the upper second insulating film forming step. Under the temperature environment, the hydrogen is efficiently diffused into the oxide semiconductor film and the resistance is reduced. Because the lower second insulating layer is provided between the oxide semiconductor film and the upper second insulating film, the bumps and the dips are less likely to be formed on and in the surface of the upper second insulating film.

(5) The lower second insulating film forming step may include forming the lower second insulating film at a forming temperature in a range from 150° C. to 270° C. The upper second insulating film forming step may include forming the upper second insulating film at a forming temperature in a range from 220° C. to 350° C. Because the lower second insulating film is formed at the temperature lower than the forming temperature of the upper second insulating film and equal to or lower than 270° C. in the lower second insulating film forming step, the formation of bumps and dips on and in the surface of the lower second insulating film is properly reduced. Because the lower second insulating film is formed at the temperature higher than the forming temperature of the lower second insulating film and equal to or lower than 220° C. in the upper second insulating film forming step, the resistance of the portion of the oxide semiconductor film can be more properly reduced. If the lower second insulating film is formed at a forming temperature of 150° C. or lower in the lower second insulating film forming step or the upper second insulating film is formed at a forming temperature of 350° C. or higher in the upper second insulating film forming step, the semiconductor device may not be able to properly exert the electrical performances. As described above, the forming temperature of the lower second insulating film is 150° C. or higher in the lower second insulating film forming step and the forming temperature of the upper second insulating film is 350° C. or lower in the upper second insulating film forming step. Therefore, the semiconductor device can properly exert the electrical performances.

(6) A material used for forming the lower second insulating film in the lower second insulating film forming step and a material used for forming the upper second insulating film in the upper second insulating film forming step may be the same. Therefore, the material cost of the second insulating film can be reduced.

### Advantageous Effect of the Invention

According to the present invention, the resistance of the oxide semiconductor film can be reduced at low cost.

### BRIEF DESCRIPTION OF THE DRAWINGS

FIG. 1 is a schematic cross-sectional view illustrating connection between a flexible circuit board and a liquid crystal panel with a driver mounted thereon and a control circuit board.

FIG. 2 is a plan view schematically illustrating a cross-sectional configuration along a long-side direction of a liquid crystal display device.

FIG. 3 is a plan view schematically illustrating wiring on an array board included in the liquid crystal panel.

FIG. 4 is a schematic cross-sectional view illustrating a cross-sectional configuration of the liquid crystal panel.

FIG. 5 is a magnified plan view illustrating a two-dimensional configuration of an array board in a display area.

FIG. 6 is a magnified plan view illustrating a two-dimensional configuration of a CF board in the display area.

FIG. 7 is a cross-sectional view illustrating a cross-sectional configuration of a portion of the array board in the display area including a display TFT and therearound.

FIG. 8 is a cross-sectional view illustrating a cross-sectional configuration of a portion of the array board in a non-display area including a non-display TFT and therearound.

FIG. 9 is a cross-sectional view illustrating an oxide semiconductor film formed in a production process of the array board.

FIG. 10 is a cross-sectional view illustrating a first interlayer insulating film formed in the production process of the array board.

FIG. 11 is a cross-sectional view illustrating a second interlayer insulating film formed in the production process of the array board.

FIG. 12 is a table including relations among forming temperature of the second interlayer insulating film, development of bumps and dips on and in a surface of the second interlayer insulating film, and sheet resistance of capacitance line in comparative experiment 1.

FIG. 13 is a table including a picture of a second interlayer insulating film of comparative example 1 formed at a forming temperature of 200° C., a picture of a second interlayer insulating film of comparative example 2 formed at a forming temperature of 300° C., determination of development of bumps or dips on surfaces of comparative examples 1 and 2, and sheet resistances of capacitive lines in comparative experiment 1.

FIG. 14 is a table including a picture of a second interlayer insulating film of comparative example 1 formed at a forming temperature of 200° C., a picture of a second interlayer insulating film of comparative example 2 formed at a forming temperature of 300° C., a picture of a second interlayer insulating film of embodiment 4 formed at a forming temperature of 200° C. and processed with annealing treatment at 350° C., determination of development of bumps or dips on surfaces of comparative examples 1 and 2, and sheet resistances of capacitive lines in comparative experiment 2 according to a second embodiment of the present invention.

FIG. 15 is a cross-sectional view illustrating a cross-sectional configuration of a portion of an array board including a display-side TFT and therearound in a display area according to a third embodiment of the present invention.

FIG. 16 is a table including a picture of a second interlayer insulating film of comparative example 1 formed at a forming temperature of 200° C., a picture of a second interlayer insulating film of comparative example 2 formed at a forming temperature of 300° C., a picture of a second interlayer insulating film of a comparative example 5 including a lower second interlayer insulating film formed at a forming temperature of 200° C. and un upper second interlayer insulating film formed at a forming temperature of 300° C., determination of development of bumps or dips on surfaces of comparative examples 1 and 2, and sheet resistances of capacitive lines in comparative experiment 3.

### MODE FOR CARRYING OUT THE INVENTION

### First Embodiment

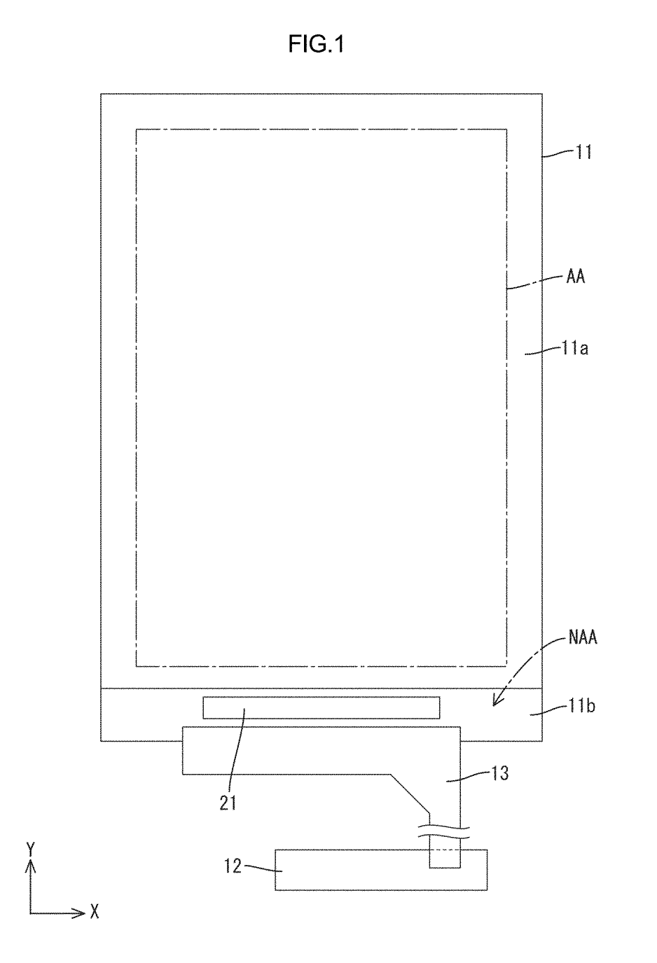

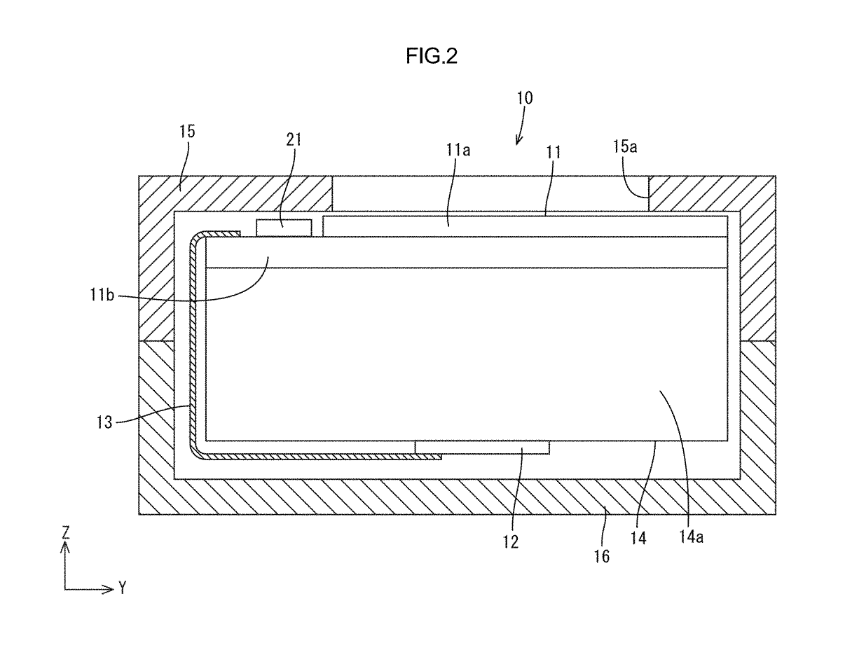

A first embodiment according to the present invention will be described with reference to FIGS. 1 to 13. In this section, a liquid crystal display device 10 according to this embodiment will be described. X-axis, Y-axis and Z-axis may be indicated in the drawings. The axes in each drawing correspond to the respective axes in other drawings. The vertical direction is defined based on FIG. 2. An upper side and a lower side in FIG. 2 correspond to a front side and aback side of the liquid crystal display device 10, respectively.

As illustrated in FIGS. 1 and 2, the liquid crystal display device 10 includes a liquid crystal panel 11 (a display device), a driver 21 (a panel driver), a control circuit board 12 (an external signal source), a flexible printed circuit board 13 (an external connector), and a backlight unit 14 (a backlight device). The liquid crystal panel 11 includes a display area AA in which images are displayed and a non-display area NAA outside the display area AA. The driver 21 is configured to drive the liquid crystal panel 11. The control circuit board 12 is configured to supply various input signals to the driver 21 from the outside. The flexible printed circuit board 13 electrically connects the liquid crystal panel 11 to the control circuit board 12 outside the liquid crystal panel 11. The backlight unit 14 is an external light source for supplying light to the liquid crystal panel 11. The liquid crystal display device 10 further includes a pair of exterior components 15 and 16 that are front and rear components used in a pair to hold the liquid crystal panel 11 and the backlight unit 14 that are attached together. An exterior component 15 on the front has an opening 15a through which images displayed in the display area AA of the liquid crystal panel 11 are viewed from the outside. The liquid crystal display device 10 according to this embodiment may be used in various kinds of electronic devices (not illustrated) such as notebook personal computers (including tablet personal computers), mobile phones (including smartphones), handheld terminals (including electronic books and PDAs), digital photo frames, and portable video game players. The liquid crystal panel 11 in the liquid crystal display device 10 is in a range between some inches to ten and some inches. Namely, the liquid crystal panel 11 is in a size that is classified as a small or a small-to-medium.

The backlight unit 14 will be described. As illustrated in FIG. 2, the backlight unit 14 includes a chassis 14a, light sources (e.g., cold cathode fluorescent tubes, LEDs, organic ELs), and an optical member. The chassis 14a has a box-like shape with an opening on the front (on a liquid crystal panel 11 side). The light sources, which are not illustrated, are disposed inside the chassis 14a. The optical member, which is not illustrated, is arranged so as to cover the opening of the chassis 14a. The optical member has a function to convert light from the light sources into planar light.

Next, the liquid crystal panel 11 will be briefly described. As illustrated in FIG. 1, the liquid crystal panel 11 has a vertically-long rectangular overall shape. The liquid crystal panel 11 includes a display area (an active area) AA that is off centered toward one of ends of a long dimension thereof (the upper side in FIG. 1). The driver 21 and the flexible printed circuit board 13 are arranged at the other end of the long dimension of the liquid crystal panel 11 (the lower side in FIG. 1). An area of the liquid crystal panel 11 outside the display area AA is a non-display area (non-active area) NAA in which images are not displayed. The non-display area NAA includes a frame-shaped area around the display area AA (a frame portion of a CF board 11a, which will be described later) and an area provided at the other end of the long dimension of the liquid crystal panel 11 (an exposed area of an array board 11b which does not overlap the CF board 11a, which will be described later). The area provided at the other end of the long dimension of the liquid crystal panel 11 includes a mounting area (an attachment area) in which the driver 21 and the flexible printed circuit board 13 are mounted. A short-side direction and a long-side direction of the liquid crystal panel 11 correspond to the X-axis direction and the Y-axis direction in each drawing. In FIG. 1, a chain line box slightly smaller than the CF board 11a indicates a boundary of the display area AA. An area outside the solid line is the non-display area NAA.

Next, the components connected to the liquid crystal panel 11 will be described. As illustrated in FIGS. 1 and 2, the control circuit board 12 is mounted to the back surface of the chassis 14a (an outer surface on a side opposite from the liquid crystal panel 11) of the backlight unit 14 with screws. The control circuit board 12 includes a substrate made of paper phenol or glass epoxy resin and electronic components mounted on the substrate and configured to supply various input signals to the driver 21. Traces (electrically conductive paths) which are not illustrated are formed in predetermined patterns. An end of the flexible printed circuit board 13 is electrically and mechanically connected to the control circuit board 12 via an anisotropic conductive film (ACF), which is not illustrated.

The flexible printed circuit board 13 (an FPC board) includes a base member made of synthetic resin having insulating property and flexibility (e.g., polyimide resin). A number of traces are formed on the base member (not illustrated). As illustrated in FIG. 2, the end of the long dimension of the flexible printed circuit board 13 is connected to the control circuit board 12 disposed on the back surface of the chassis 14a as described above. The other end of the long dimension of the flexible printed circuit board 13 is connected to the array board 11b in the liquid crystal panel 11. The flexible printed circuit board 13 is bent or folded back inside the liquid crystal display device 10 such that a cross-sectional shape thereof forms a U-like shape. At the ends of the long dimension of the flexible printed circuit board 13, portions of the traces are exposed to the outside and configured as terminals (not illustrated). The terminals are electrically connected to the control circuit board 12 and the liquid crystal panel 11. With this configuration, input singles supplied by the control circuit board 12 are transmitted to the liquid crystal panel 11.

As illustrated in FIG. 1, the driver 21 is on an LSI chip including drive circuits. The driver 21 is configured to operate according to signals supplied by the control circuit board 12, which is a signal source, to process the input signal supplied by the control circuit board 12, to generate output signals, and to output the output signals to the display area AA in the liquid crystal panel 11. The driver 21 has a vertically-long rectangular shape (an elongated shape that extends along the short side of the liquid crystal panel 11) in a plan view. The driver 21 is directly connected to the non-display area NAA of the liquid crystal panel 11 (or the array board 11b, which will be described later), that is, mounted by the chip-on-glass (COG) mounting method. A long-side direction and a short-side direction of the driver 21 correspond to the X-axis direction (the short-side direction of the liquid crystal panel 11) and the Y-axis direction (the long-side direction of the liquid crystal panel 11), respectively.

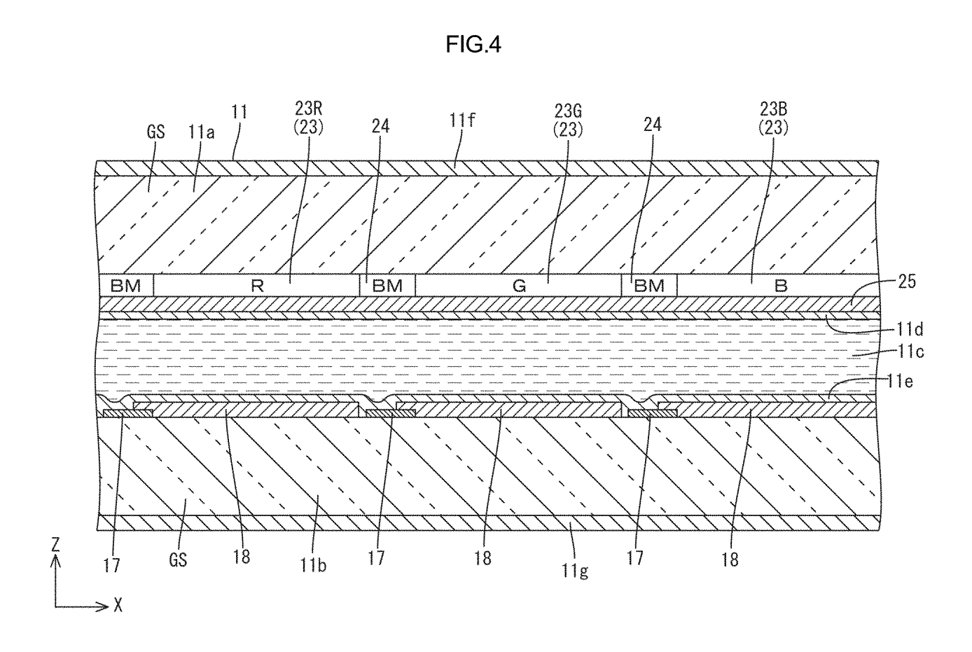

The configuration of the liquid crystal panel 11 will be described in detail. As illustrated in FIG. 4, the liquid crystal panel 11 includes a pair of boards 11a and 11b and a liquid crystal layer 11c (liquid crystals) between the boards 11a and 11b. The liquid crystal layer 11c includes liquid crystal molecules having optical characteristics that vary according to application of electric field. The boards 11a and 11b are bonded together with a sealing agent, which is not illustrated, with a gap therebetween. A size of the gap corresponds to the thickness of the liquid crystal layer 11c. One of the boards 11a and 11b on the front is the CF board 11a (a counter board) and one on the rear (on the back) is the array board (a semiconductor device, an active matrix board) 11b. The CF board 11a and the array board 11b include glass substrates GS that are substantially transparent (i.e., having high light transmissivity). Various films are formed in layers on each glass substrate GS. As illustrated in FIGS. 1 and 2, the CF board 11a has a short dimension substantially equal to a short dimension of the array board 11b and a long dimension smaller than a long dimension of the array board 11b. The CF board 11a is bonded to the array board 11b with one of ends of the long dimension (the upper end in FIG. 1) aligned with a corresponding edge of the array board 11b. A predetermined area of the other end of the long dimension of the array board 11b (the lower end in FIG. 1) does not overlap the CF board 11a and front and back plate surfaces in the area are exposed to the outside. The mounting area in which the driver 21 and the flexible printed circuit board 13 are mounted is provided in this area. Alignment films 11d and 11e are formed on inner surfaces of the boards 11a and 11b, respectively, for alignment of the liquid crystal molecules included in the liquid crystal layer 11c. Polarizing plates 11f and 11g are attached to outer surfaces of the boards 11a and 11b, respectively.

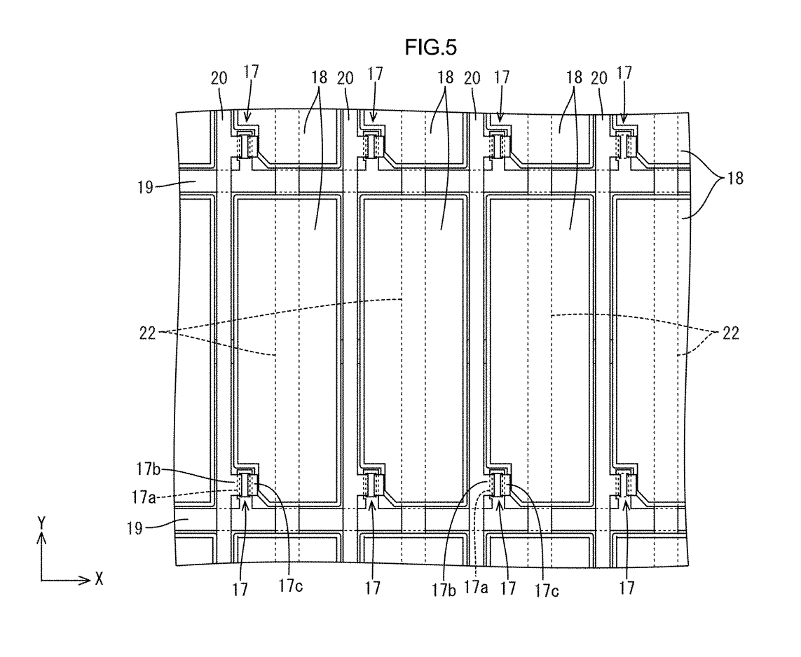

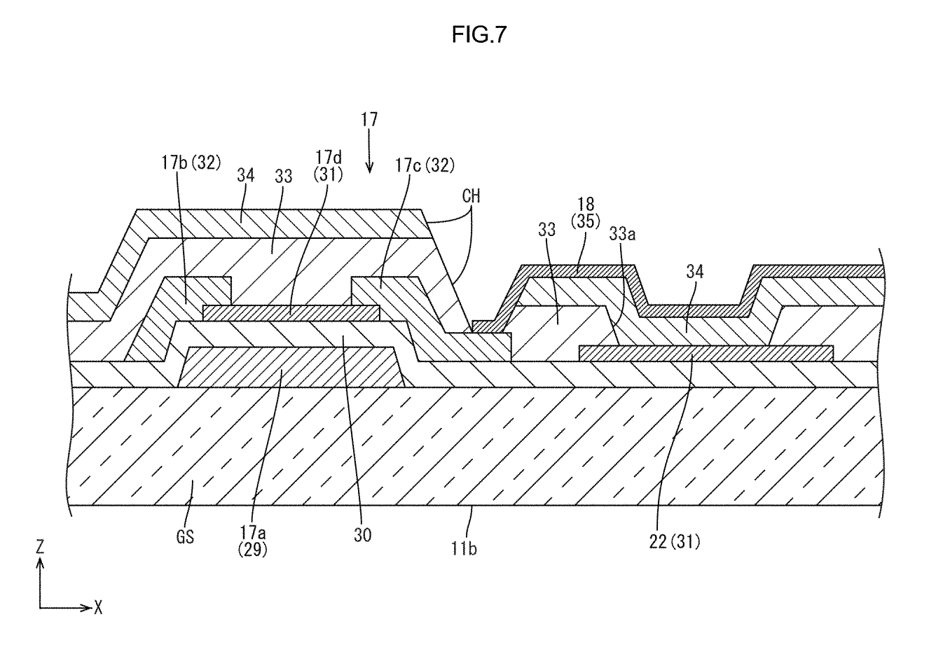

A configuration of the array board 11b in the display area AA will be described. As illustrated in FIG. 5, display-side TFTs 17 (transistors, display-side transistors) each including three electrodes 17a to 17c and pixel electrodes 18 are arranged in a matrix on an inner surface of the array board 11b in the display area AA (on a liquid crystal layer 11c side, on an opposite surface opposed to the CF board 11a) along a plate surface of the array board 11b. The display-side TFTs are switching components. Furthermore, gate traces 19 and source traces 20 are formed in a lattice pattern to surround the display-side TFTs 17 and the pixel electrodes 18. The gate traces 19 and the source traces 20 are connected to gate electrodes 17a and source electrodes 17b of the display-side TFTs 17, respectively. The pixel electrodes 18 are connected to drain electrodes 17c of the display-side TFTs 17. The display-side TFTs 17 include channels 17d formed from an oxide semiconductor film 31 (see FIG. 7), which will be described later. The channels 17d are connected to the source electrodes 17b and the drain electrodes 17c. Through driving of the display-side TFTs 17, application of electrical potentials to the pixel electrodes 18 is controlled. A cross-sectional configuration of the display-side TFTs 17 will be described in detail later. Capacitive traces 22 (auxiliary capacitance traces, storage capacitive traces, Cs traces) are formed on the array board 11b to extend parallel to the source traces 20 and overlapping the pixel electrodes 18. The capacitive traces 22 and the overlapping pixel electrodes 18 hold capacitances therebetween. Electrical potentials charged at the pixel electrodes 18 are held for a certain period. The capacitive traces 22 and the source traces 20 are alternately arranged with respect to the X-axis direction. Each source trace 20 is arranged between the pixel electrodes 18 adjacent to each other with respect to the X-axis direction. Each capacitive trace 22 is arranged to cross about the middle of the corresponding pixel electrode 18 with respect to the X-axis direction.

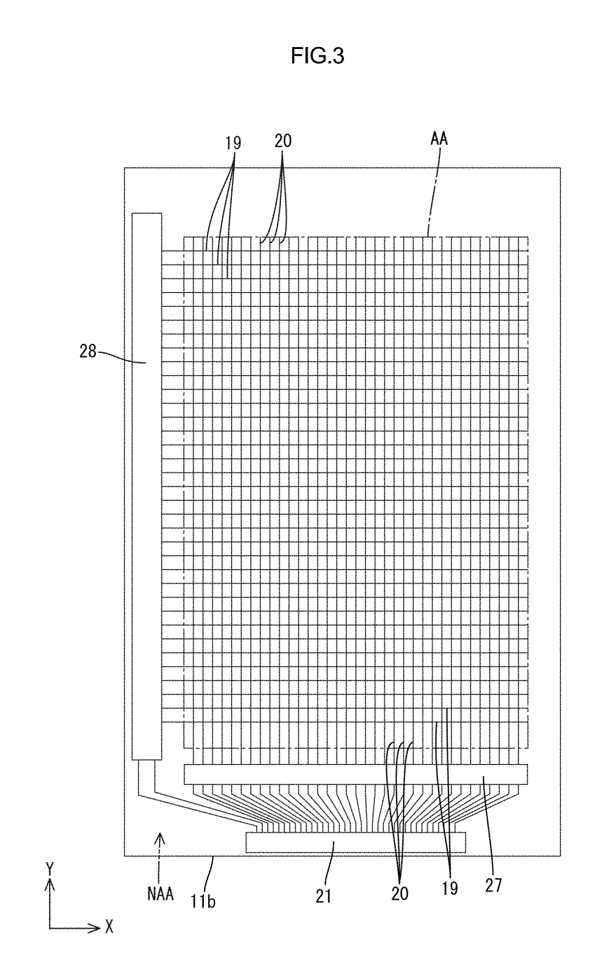

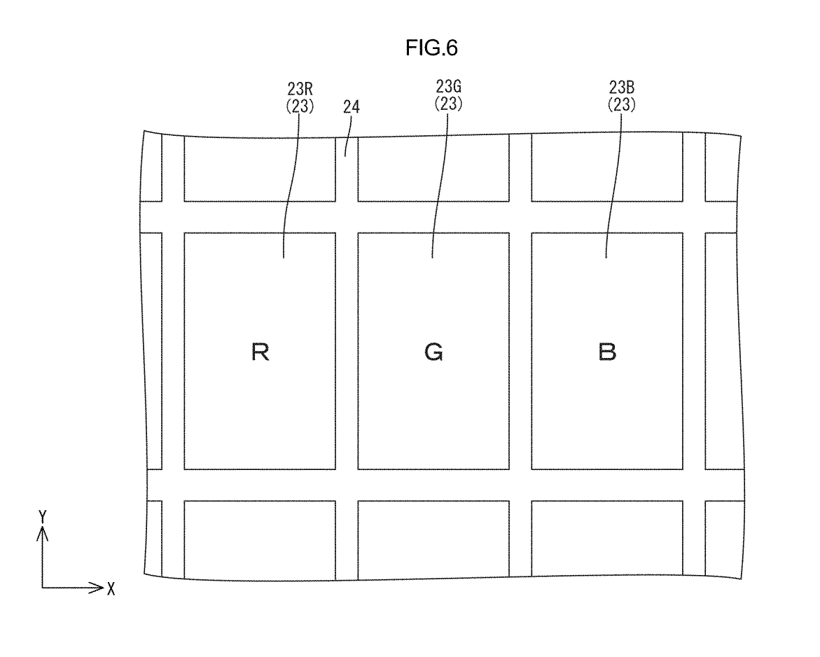

As illustrated in FIGS. 3 and 6, color filters 23 are formed in a matrix on an inner surface of the CF board 11a in the display area AA (on the liquid crystal layer 11c side, an opposite surface opposed to the array board 11b) to overlap the pixel electrodes 18 on the array board 11b in a plan view, respectively. The color filters 23 are arranged along a plate surface of the CF board 11a. The color filters 23 include groups of three colors of color portions 23R, 23G, and 23B exhibiting red, green, and blue. The color portions are repeatedly and alternately arranged along a row direction (the X-axis direction). A large number of the groups of the color portions are arranged along a column direction (the Y-axis direction). Each of the color portions 23R, 23G, and 23B of the color filters 23 selectively passes light in a specific wavelength range of its color (a visible light ray). As illustrated in FIG. 6, an outline of each of the color portions 23R, 23G, and 23B is a vertically-long rectangular along an outline of each pixel electrode 18 in a plan view. A light blocking portion 24 in a lattice pattern (a black matrix) is formed between the color portions 23R, 23G, and 23B of the color filters 23 for reducing color mixture. The light blocking portion 24 is arranged to overlap the gate traces 19, the source traces 20, and the capacitive traces 22 on the array board 11b in the plan view. As illustrated in FIG. 3, a common electrode 25 is formed on surface of the color filters 23 and the light blocking portion 24 opposite the pixel electrodes 18 on the array board 11b. An electrical potential of the common electrode 25 is held constantly at a reference electrical potential. When the display-side TFTs 17 are driven and electrical potentials are applied to the pixel electrodes 18 connected to the display-side TFTs 17, potential differences are created between the common electrode 25 and the pixel electrodes 18. Alignment of the liquid crystal molecules in the liquid crystal layer 11c varies according to the potential differences between the common electrode 25 and the pixel electrodes 18. As a result, polarization of transmitting light varies. An amount of transmitting light of the liquid crystal panel 11 is individually controlled per pixel electrode 18 and thus a specified color image is displayed.

Next, a configuration of a portion of the array board 11b in the non-display area NAA will be described. As illustrated in FIG. 3, in a portion of the array board 11b in the non-display area NAA adjacent to a short side of the display area AA, a column control circuit 27 is formed. In a portion of the array board 11b in the non-display area NAA adjacent to a long side of the display area AA, a row control circuit 28 is formed. The source traces 20 and the capacitive traces 22 are extended from the display area AA and connected to the column control circuit 27. The gate traces 19 are extended from the display area AA and connected to the row control circuit 28. The column control circuit 27 and the row control circuit 28 are connected to the driver 21 and configured to perform controls for supplying signals output from the driver 21 to the display-side TFTs 17. The column control circuit 27 and the row control circuit 28 are monolithically formed on the array board 11b using the oxide semiconductor film 31 as a base. The oxide semiconductor film 31 is used to form the channels 17d of the display-side TFT 17. According to the configuration, a control circuit for supplying output signals to the display-side TFTs 17 is provided. The control circuit includes non-display-side TFTs 26 (non-display-side transistors). The non-display-side TFTs 26 are arranged on a plate surface of the array board 11b in a non-display area NAA (a column control circuit 27 and a row control circuit 28). The non-display-side TFTs 26 are formed on the array board 11b by patterning with a known photolithography method simultaneously with the display-side TFTs 17 that are formed by patterning in the production process of the array board 11b. A cross-sectional configuration of the non-display-side TFTs 26 will be described in detail later. The column control circuit 27 includes a switching circuit (an RGB switching circuit) for distributing image signals included in the output signals from the driver 21 to the source traces 20. The row control circuit 28 includes a scanning circuit and a buffer circuit. The scanning circuit is for scanning the gate traces 19 in sequence with signals supplied to the gate traces 19 with specified timing. The buffer circuit is for amplifying scanning signals.

Various films formed in layers on an inner surface of a glass substrate GS of the array board 11b with the known photolithography method will be described. As illustrated in FIG. 7, on the glass substrate GS of the array board 11b, a first metal film 29 (a gate metal film), a gate insulating film 30, the oxide semiconductor film 31, a second metal film 32 (a source metal film), a first interlayer insulating film 33 (a first insulating film), a second interlayer insulating film 34 (a second insulating film), a transparent electrode film 35, and the alignment film lie are formed in layers in this sequence from the lower layer side. The alignment film lie is illustrated in FIG. 4 but not in FIG. 7.

The first metal film 29 is a laminated film of titanium (Ti) and copper (Cu). At least the gate traces 19 are formed from the first metal film 29. The gate insulating film 30 is made of inorganic material such as silicone oxide (SiO2) and layered at least on the first metal film 29. The oxide semiconductor film is layered on the gate insulating film 30. The oxide semiconductor film 31 is a thin film made of substantially transparent oxide semiconductor material (having high light transmissivity). The oxide semiconductor material of the oxide semiconductor film 31 may be an In—Ga—Zn—O based semiconductor (indium gallium zinc oxide) containing indium (In), gallium (Ga), zinc (Zn), and oxygen (O). The In—Ga—Zn—O based semiconductor is a ternary oxide containing indium (In), gallium (Ga), and zinc (Zn). The ratio (the compound ratio) of indium to gallium and zinc is not limited to a specific ratio. Examples of the ratio include: In:Ga:Zn=2:2:1, In:Ga:Zn=1:1:1, In:Ga:Zn=1:1:2. In this embodiment, the ratio of Indium to gallium and zinc in the In—Ga—Zn—O based semiconductor is 1:1:1. The oxide semiconductor (the In—Ga—Zn—O based semiconductor) may have amorphous properties but preferably have crystalline properties, that is, including crystalline substances. A preferable oxide semiconductor having crystalline properties may be a crystalline In—Ga—Zn—O based semiconductor with the c-axis is substantially perpendicular to a layer surface. An example of crystalline structures of such an oxide semiconductor (the In—Ga—Zn—O based semiconductor) is disclosed in Japanese Unexamined Patent Application Publication No. 2012-134475. Whole disclosure of Japanese Unexamined Patent Application Publication No. 2012-134475 is incorporated by reference.

The second metal film 32 is a laminated film of titanium (Ti) and copper (Cu) layered at least on the oxide semiconductor film 31. At least the source traces 20 are formed from the first metal film 29. The first interlayer insulating film 33 is made of inorganic material such as silicon oxide (SiO2) and layered at least on the second metal film 32. The second interlayer insulating film 34 is made of inorganic material such as silicon nitride (SiNx) and layered at least on the first interlayer insulating film 33. The transparent electrode film 35 is made of transparent electrode material such as indium tin oxide (ITO) and zinc oxide (ZnO) and layered at least on the second interlayer insulating film 34. At least the pixel electrodes 18 are formed from the transparent electrode film 35.

The cross-sectional configuration of the display-side TFTs 17 will be described in detail. As illustrated in FIG. 7, each display-side TFT 17 includes the gate electrode 17a, the channel 17d, the source electrode 17b, and the drain electrode 17c. The gate electrode 17a is formed from the first metal film 29 that forms the gate traces 19. The channel 17d is formed from the oxide semiconductor film 31 and layered on the gate electrode 17a via the gate insulating film 30 to overlap the gate electrode 17a in a plan view. The source electrode 17b is formed from the second metal film 32 that forms the source traces 20 and arranged in an upper layer relative to the channel 17d. The source electrode 17b is connected to one of ends of the channel 17d. The drain electrode 17c is formed from the second metal film 32 that forms the source traces 20 and arranged in an upper layer relative to the channel 17d. The drain electrode 17c is connected to the other one of ends of the channel 17d. An end of the source electrode 17b opposite from the end on the channel 17d side is connected to the source trace 20 (see FIG. 5). An end of the drain electrode 17c opposite from the end on the channel 17d side is connected to the pixel electrode 18 via a contact hole CH that is a through hole formed in the first interlayer insulating film 33 and the second interlayer insulating film 34. Ends of the channel 17d connected to the source electrode 17b and the drain electrode 17c are covered with the first interlayer insulating film 33 made of silicon oxide. The oxide semiconductor film 31 that forms the channels 17d has electron mobility 20 to 50 times higher than electron mobility of an amorphous silicon thin film. Therefore, the size of the display-side TFTs 17 can be easily reduced and an amount of light transmitting through the pixel electrodes 18 can be maximized. This configuration is suitable for increasing definition and decreasing power consumption. The display-side TFTs 17 are inverted staggered type TFTs having layer structures similar to the layer structures of TFTs including regular amorphous silicon thin films.

Next, the cross-sectional configuration of the non-display-side TFTs 26 will be described in detail. As illustrated in FIG. 7, each non-display-side TFT 26 includes a first gate electrode 26a (a lower gate electrode), a channel 26d, a source electrode 26b, a drain electrode 26c, and a second gate electrode 26e (an upper gate electrode). The first gate electrode 26a is formed from the first metal film 29 that forms the gate traces 19. The channel 26d is formed from the oxide semiconductor film 31 and arranged in an upper layer relative to the first gate electrode 26a via the gate insulating film 30 to overlap the first gate electrode 26a in a plan view. The source electrode 26b is formed from the second metal film 32 that forms the source traces and arranged in an upper layer relative to the channel 26d. The source electrode 26b is connected to one of ends of the channel 26d. The drain electrode 26c is formed from the second metal film 32 that forms the source traces 20 and arranged in an upper layer relative to the channel 26d. The drain electrode 26c is connected to the other end of the channel 26d. The second gate electrode 26e is formed from the transparent electrode film 35 that forms the pixel electrodes 18 and arranged in an upper layer relative to the source electrode 26b and the drain electrode 26c to overlap the channel 26d in the plan view. Each non-display-side TFT 26 has a double gate structure including two gate electrodes 26a and 26e that sandwich the channel 26d in the top-bottom direction of the layers. Furthermore, the non-display-side TFT 26 includes only the first interlayer insulating film 33, which is an inorganic insulating film, between the second gate electrode 26e and the channel 26d, that is, the second interlayer insulating film 34 and an organic insulating film do not exit therebetween. Therefore, a distance between the second gate electrode 26e and the channel 26d is small. According to the configuration, the electron mobility of the channels 26d of the non-display-side TFTs 26 are significantly high and thus the size of the non-display-side TFTs 26 can be reduced. Therefore, the area of the non-display area NAA can be reduced. This configuration is preferable for reducing a frame size of the liquid crystal panel 11.

Cross-sectional configurations of the capacitive traces 22 and the pixel electrodes 18 arranged to overlap one another will be described in detail. As illustrated in FIG. 7, the capacitive traces 22 are formed from the oxide semiconductor film 31 that forms the channels 17d of the TFTs 17 and the channels 26d of the TFTs 26 and arranged in an upper layer relative to the gate insulating film 30 and in a lower layer relative to the first interlayer insulating film 33. The capacitive traces 22 have electrical resistances smaller than the electrical resistance of the channels 17d of the TFTs 17 and the channels 26d of the TFTs 26. Therefore, electrical signals with sufficient capacitances between the capacitance traces 22 and the pixel electrodes 18 are properly transmitted. The channels 17d of the TFTs 17 and the channel 26d of the TFTs 26 have the resistances higher than the resistances of the capacitive traces 22. Namely, the oxide semiconductor film 31 includes the capacitive traces 22 (the low resistance portion, a portion) having the lower electrical resistances and the channels 17d and 26d (the other portion) having the higher electrical resistances separated from one another.

As described above, the capacitive traces 22 are formed from the oxide semiconductor film 31 that forms the channels 17d and 26d separated from one another. Furthermore, the capacitive traces 22 have the lower electrical resistances. According to the configuration, the first interlayer insulating film 33 among the first interlayer insulating film 33 and the second interlayer insulating film 34 between the capacitive traces 22 and the pixel electrodes 18 includes holes 33a at positions overlapping the capacitive traces 22 and the pixel electrodes 18 as illustrated in FIG. 7. Because the holes 33a are formed in the first interlayer insulating film 33, portions of the capacitive traces 22 facing the holes 33a are directly layered on the second interlayer insulating film 34 from the upper layer side via the holes 33a. Only the second interlayer insulating film 34 exists between the portions of the capacitive traces 22 facing the holes 33a and the pixel electrodes 18. The second interlayer insulating film 34 is made of silicon nitride as described earlier. The second interlayer insulating film 34 is formed through chemical reaction between dichlorosilane (SiH2Cl2) and ammonia (NH3) using a low pressure CVD system or through chemical reaction between silane (SiH4) and ammonia (NH3) using a plasma CVD system. Namely, hydrogen (H2) is generated in the film forming step and the second interlayer insulating film 34 contains at least a small amount of hydrogen. During the formation of the second interlayer insulating film 34, portions of the second interlayer insulating film 34 are directly layered on the portions of the capacitive traces 22 formed from the oxide semiconductor film 31 facing the holes 33a. The hydrogen contained in the second interlayer insulating film 34 is diffused into the capacitive traces 22. When the oxide semiconductor film 31 receives the hydrogen, an electrically shallow impurity level is created due to the hydrogen and thus the electrical resistance decreases. With the hydrogen from the second interlayer insulating film 34 directly layered on the capacitive traces 22 via the holes 33a, the resistances of the capacitive traces 22 are reduced. The capacitive traces 22 are physically separated from the channels 17d and 26d that are the other portions of the oxide semiconductor film 31. Therefore, the hydrogen received by the capacitance traces 22 is not diffused into the channels 17d and 26d. According to the configuration, the electrical resistances of the capacitive traces 22 and the electrical resistances of the channels 17d and 26d are properly maintained at target resistances. Therefore, the capacitive traces 22 and the channels 17d and 26d can properly exert electrical performances.

This embodiment has the configuration described above. Next, a method of producing the array board 11b of the liquid crystal panel 11 will be described in detail. The array board 11b is produced through a first metal film forming step, a gate insulating film forming step, an oxide semiconductor film forming step, a second metal film forming step, a first interlayer insulating film forming step (a first insulating film forming step), a hole forming step, a second interlayer insulating film forming step (a second insulating film forming step), a contact hole forming step, and a transparent electrode film forming step. The first metal film forming step is for forming the first metal film 29. The gate insulating film forming step is for forming the gate insulating film 30. The second metal film forming step is for forming the second metal film 32. The hole forming step is for forming the holes 33a in the first interlayer insulating film 33. The second interlayer insulating film forming step is for forming the second interlayer insulating film 34. The contact hole forming step is for forming the contact holes CH in the first interlayer insulating film 33 and the second interlayer insulating film 34. The transparent electrode film forming step is for forming the transparent electrode film 35.

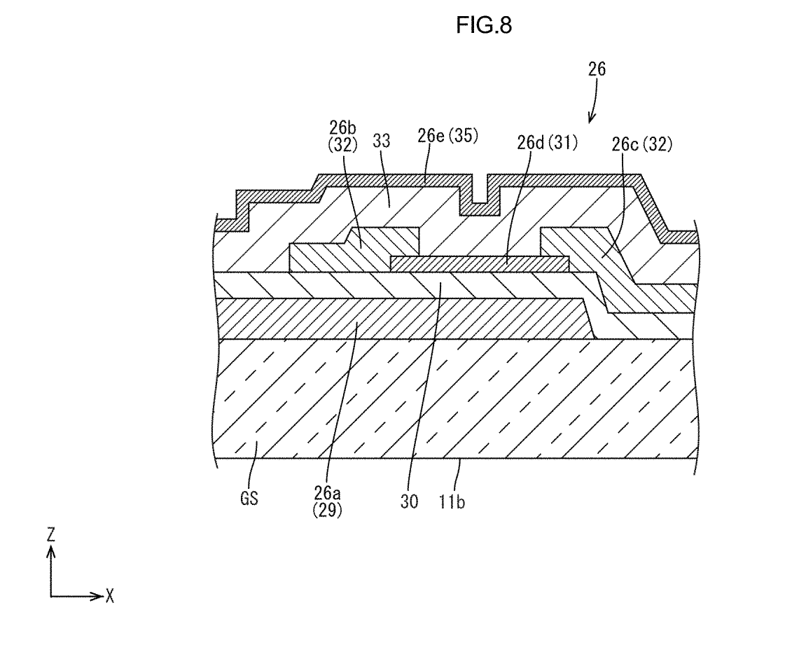

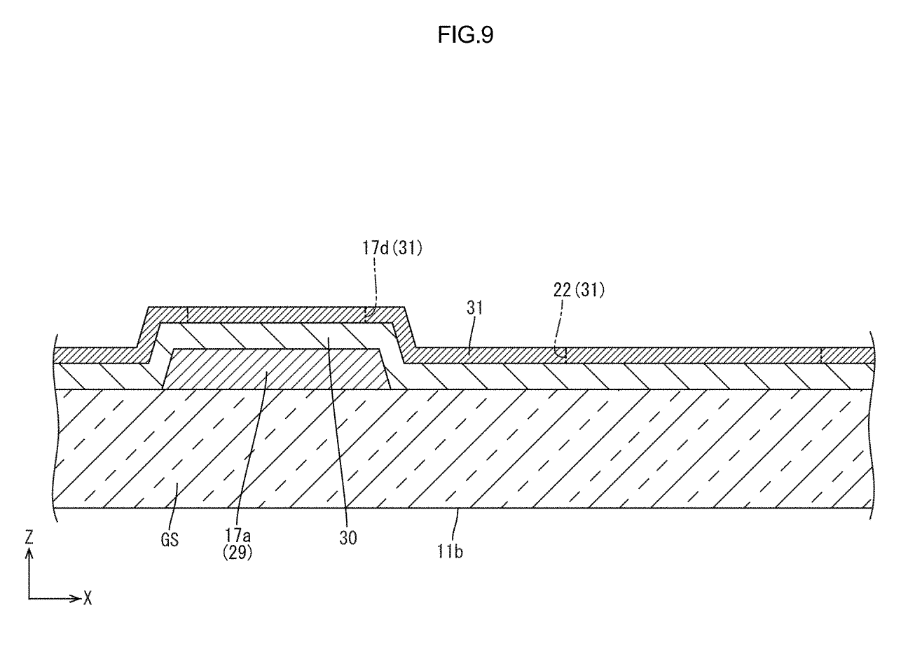

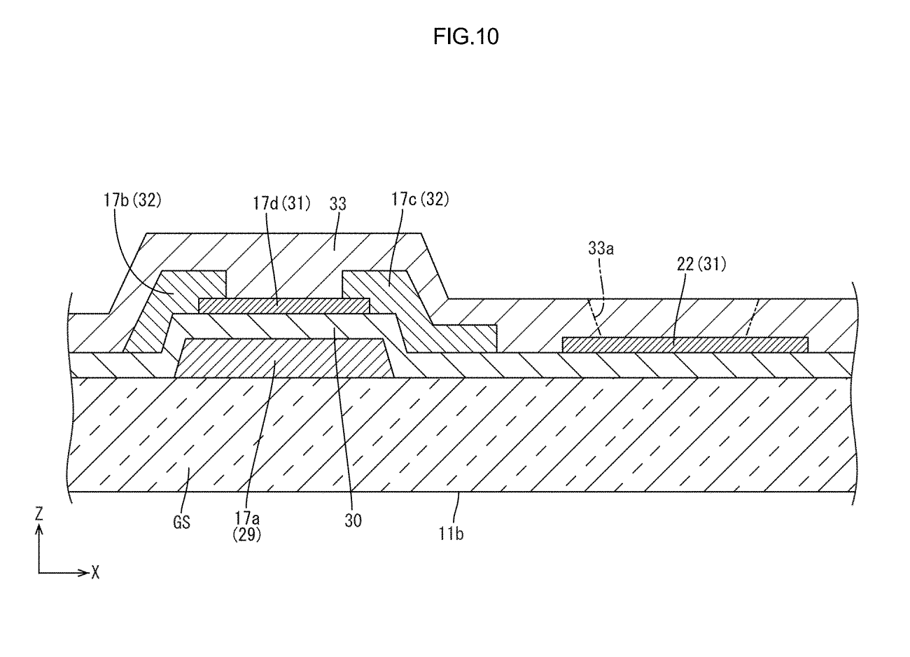

In the first metal film forming step, the first metal film 29 is formed in a solid pattern on the surface of the glass substrate GS of the array board 11b. The first metal film 29 is patterned and the gate electrodes 17a are formed as illustrated in FIG. 9. The gate traces 19 and the first gate electrodes 26a are formed at the same time when the first metal film 29 is patterned (see FIGS. 5 and 8). In the gate insulating film forming step, the gate insulating film 30 made of silicon oxide (SiO2) is formed in a solid pattern on upper layer sides of the glass substrate GS and the first metal film 29. In the oxide semiconductor film forming step, the oxide semiconductor film 31 is formed in a solid pattern on an upper side of the gate insulating film 30 and patterned as indicated with chain lines in FIG. 9. As illustrated in FIG. 10, the channels 17d and the capacitive traces 22 are formed such that they are separated from one another. The channels 26d of the non-display-side TFTs 26 are formed at the same time when the oxide semiconductor film 31 is patterned (see FIG. 8). There is no difference between the electrical resistance of the channels 17d and 26d and the electrical resistance of the capacitive traces 22.

In the second metal film forming step, the second metal film 32 is formed in a solid pattern and patterned. The source electrodes 17b and the drain electrodes 17c are formed as illustrated in FIG. 10. The source electrodes 26b and the drain electrodes 26c of the non-display-side TFTs 26 and the source traces 20 are formed at the same time when the second metal film 32 is patterned (see FIGS. 5 and 8). In the first interlayer insulating film forming step, the first interlayer insulating film 33 made of silicon oxide (SiO2) is formed in a solid pattern on the upper sides of the second metal film 32, a portion of the oxide semiconductor film 31, and a portion of the gate insulating film 30. In the hole forming step, the first interlayer insulating film 33 is patterned as indicated by chain lines in FIG. 10. As a result, the holes are formed in the first interlayer insulating film 33 at the positions overlapping the capacitive traces 22. A large portion of the capacitive traces 22 in the middle with respect to a width direction thereof is exposed to the outside on the upper side through the holes 33a. In the second interlayer insulating film forming step, the second interlayer insulating film 34 made of silicon nitrogen (SiNx) is formed on upper sides of the first interlayer insulating film 33 and the capacitive traces 22. The forming temperature is preferably in a range from 220° C. to 270° C.

In the second interlayer insulating film forming step, the second interlayer insulating film 34 is formed through chemical reaction between dichlorosilane (SiH2Cl2) and ammonia (NH3) using a low pressure CVD system or through chemical reaction between silane (SiH4) and ammonia (NH3) using a plasma CVD system. Namely, hydrogen (H2) is generated in the forming step of the second interlayer insulating film 34 and the second interlayer insulating film 34 contains hydrogen. The portions of the second interlayer insulating film 34 are directly layered on the portions of the capacitive traces 22 formed from the oxide semiconductor film 31 facing the holes 33a via the holes 33a. The hydrogen contained in the second interlayer insulating film 34 layered on the capacitive traces 22 on the upper layer side is diffused into the capacitive traces 22. As a result, the resistances of the capacitive traces 22 formed from the oxide semiconductor film 31 are reduced. The capacitive traces 22 are physically separated from the channels 17d and 26d that are the other portions formed from the oxide semiconductor film 31. Therefore, the hydrogen in the capacitive traces 22 is not diffused into the channels 17d and 26d. According to the configuration, the electrical resistances of the capacitive traces 22 are sufficiently reduced to the target. Furthermore, because the electrical resistances of the channels 17d and 26d are less likely to be unnecessarily reduced, the capacitive traces 22 and the channels 17d and 26d can properly exert the electrical performances.

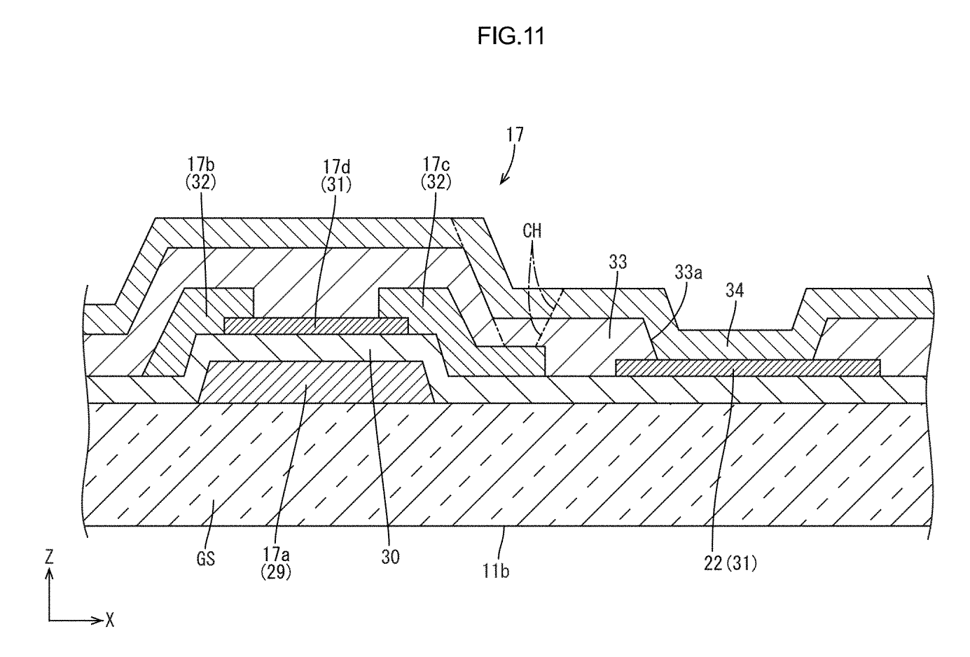

In the contact hole forming step performed after the second interlayer insulating film forming step, the first interlayer insulating film 33 and the second interlayer insulating film 34 are patterned as indicated by the chain lines in FIG. 11. As illustrated in FIG. 11, the contact holes CH are formed in the first interlayer insulating film 33 and the second interlayer insulating film 34 at the positions overlapping the ends of the drain electrodes 17c opposite from the channels 17d. In the contact hole forming step, portions of the second interlayer insulating film 34 at least overlapping the non-display-side TFTs 26 in the non-display area NAA are removed (see FIG. 8). In the transparent electrode forming step performed after the contact hole forming step, the transparent electrode film 35 is formed in a solid pattern and patterned to form the pixel electrodes 18 and the second gate electrode 26e as illustrated in FIGS. 7 and 8. As illustrated in FIG. 7, the pixel electrodes 18 are electrically connected to the drain electrodes 17c in the lower layer via the contact holes CH. As illustrated in FIG. 8, the second gate electrodes 26e are arranged to overlap the channels 26d with the first interlayer insulating film 33 between the second gate electrodes 26e and the channels 26d.

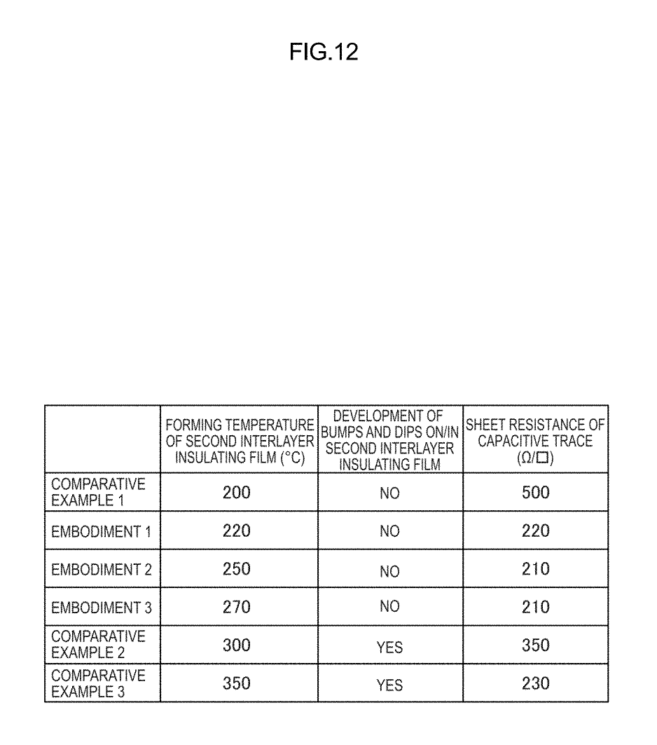

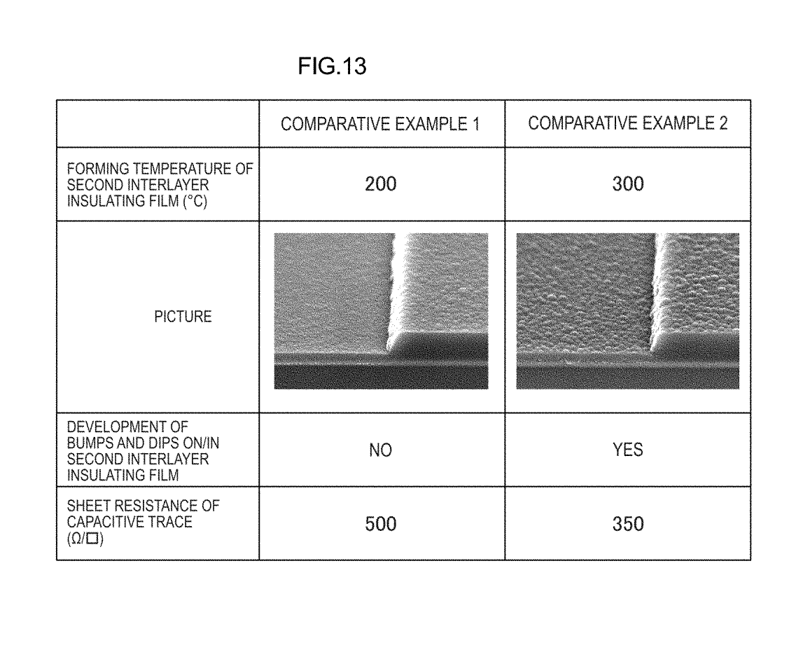

Comparative experiment 1 was conducted to examine how the electrical resistances of the capacitive traces 22 formed from the oxide semiconductor film 31 and development of bumps and dips on and in the surface of the second interlayer insulating film 34 vary according to a variation in temperature during formation of the second interlayer insulating film 34. In comparative experiment 1, the second interlayer insulating films 34 were formed at different temperatures: at 200° C. in comparative example 1, at 220° C. in embodiment 1, at 250° C. in embodiment 2, at 270° C. in embodiment 3, at 300° C. in comparative example 2, and at 350° C. in comparative example 3. Surfaces of the second interlayer insulating film 34 in each of the comparative examples 1 to 3 and embodiments 1 to 3 was inspected with a scanning electron microscope (SEM) to determine whether bumps and dips were formed. Furthermore, sheet resistances (in unit of “Ω/□”) which correspond to the reduced electrical resistances of the capacitive traces 22 that are arranged in the lower layer relative to the second interlayer insulating were measured. The results are illustrated in FIGS. 12 and 13. FIG. 12 is a table including determinations of the development of the bumps and the dips on and in the surfaces of the second interlayer insulating films 34 and the sheet resistances of the capacitive traces 22 in comparative examples 1 to 3 and embodiments 1 to 3. FIG. 13 is a table including pictures of the surfaces of the second interlayer insulating films 34 in comparative examples 1 and 2 captured by the SEM, determinations of development of the bumps and the dips, and the sheet resistances of the capacitive traces 22. The determination of the development of the bumps and the dips on and in the second interlayer insulating films 34 may be made based on subjective views of an observer through visual inspections. It is more preferable that the determination is made based on objective criteria. For example, surface roughness Ra may be measured for the second interlayer insulating films 34 and the development of the bumps and the dips may be determined as: “not present” if the surface roughness Ra is equal to or lower than a threshold (e.g., 5 μm or lower); and “present” if the surface roughness Ra is over the threshold. Regarding the sheet resistances of the capacitive traces 22, it is determined that the electrical resistances are sufficiently reduced if the sheet resistances are below 500 Ω/□.

The results of comparative experiment 1 will be described. As illustrated in FIG. 12, in comparative example 1, the bumps and the dips were not formed on and in the second interlayer insulating film 34 but the sheet resistances of the capacitive traces 22 was 500Ω/□. Therefore, it was determined that the resistance of the capacitive traces 22 was not sufficiently reduced. In embodiments 1 and 2, the bumps and the dips were not formed in the surfaces of the second interlayer insulating films 34 and the sheet resistances of the capacitive traces 22 were 220Ω/□ and 210Ω/□, respectively. Therefore, it was determined that the resistances of the capacitive traces 22 were sufficiently reduced. When the forming temperatures of the second interlayer insulating films 34 were below 220° C., sufficient amounts of hydrogen were not diffused to the capacitive traces 22 formed from the oxide semiconductor films 31 during the formation of the second interlayer insulating films 34. Therefore, it is determined that the resistances of the capacitive traces 22 formed from the oxide semiconductor films 31 are less likely to be sufficiently reduced.

In embodiments 2 and 3, the sheet resistances of the capacitive traces 22 are 350Ω/□ and 230Ω/□, respectively. Although the resistances of the capacitive traces 22 are sufficiently reduced, the bumps and the dips are formed on and in the surfaces of the second interlayer insulating films 34. The picture of the second interlayer insulating film 34 with the bumps and the dips formed on and in the surface in comparative example 2 is presented in FIG. 13. In embodiments 2 and 3, the sheet resistances of the capacitive traces 22 are both 210Ω/□. The resistances of the capacitive traces 22 are sufficiently reduced and the bumps and the dips are not formed on and in the surfaces of the second interlayer insulating films 34. Although pictures of the second interlayer insulating films 34 in embodiments 1 to 3 are not presented, the second interlayer insulating films 34 in embodiments 1 to 3 look similar to the picture of the second interlayer insulating film 34 in comparative example 1 that does not have the bumps and the dips on and in the surfaces. From the results, it is clear that the bumps and the dips are more likely to be formed on and in the surfaces of the second interlayer insulating films 34 when the forming temperatures of the second interlayer insulating films 34 are above 270° C. The bumps and the dips formed on and in the surfaces of the second interlayer insulating films 34 may result from diffusion of elements contained in the oxide semiconductor films 31 such as zinc into the second interlayer insulating films 34.

In embodiments 1 to 3, the forming temperatures of the second interlayer insulating films 34 are in a range from 220° C. to 270° C. Therefore, hydrogen contained in the second interlayer insulating films 34 is sufficiently diffused into the capacitive traces formed from the oxide semiconductor films 31. Furthermore, the elements such as zinc contained in the oxide semiconductor films 31 are less likely to be diffused into the second interlayer insulating films 34. Therefore, the capacitive traces 22 properly exert the electrical performances. Sufficient amounts of capacitances are held between the pixel electrodes 18 and the capacitive traces 22. Furthermore, the pixel electrodes 18 formed from the transparent electrode film 35 layered on the second interlayer insulating films 34 in the upper layers are properly brought into intimate contact with the second interlayer insulating films 34. Therefore, the pixel electrodes 18 are less likely to be removed. Furthermore, a decrease in light transmissivity resulting from the bumps and the dips is less likely to occur.

As described above, the array board 11b (the semiconductor device) according to this embodiment includes the oxide semiconductor film 31, the first interlayer insulating film 33 (the first insulating film), and the second interlayer insulating film 34 (the second insulating film). The oxide semiconductor film 31 includes the portions that form the capacitive traces 22 and the other portions that form the channels 17d and 26d. The portions are the lower resistance portions having the electrical resistances lower than the electrical resistances of the other portions. The capacitive traces 22 that are the lower resistance portions are separated from the channels 17d and 26d that are the other portions. The first interlayer insulating film 33 formed in the upper layer relative to the oxide semiconductor film 31 includes the holes 33a at the positions overlapping the capacitive traces 22. The second interlayer insulating film 34 is formed in the upper layer relative to the first interlayer insulating film 33. The second interlayer insulating film 34 contains hydrogen.

The portions of the second interlayer insulating film 34 are directly layered on the capacitive traces 22 that are the portions of the oxide semiconductor film 31 facing the holes 33a via the holes 33a. Therefore, the hydrogen contained in the second interlayer insulating film 34 is diffused into the capacitive traces 22 that are the portions of the oxide semiconductor film 31 facing the holes 33a and thus the resistances of the capacitive traces 22 are reduced. Because the resistances of the capacitive traces 22 that are the portions of the oxide semiconductor film 31 are reduced using the second interlayer insulating film 34, the special treatment such as the hydrogen plasma treatment that is included in the known method is not required. Therefore, a low production cost can be achieved. Furthermore, if capacitive traces that are low resistance portions of an oxide semiconductor film and channels that are other portions of the oxide semiconductor film are connected to one another, hydrogen diffused from the second interlayer insulating film 34 into the capacitive traces that are the low resistance portions may be diffused into the channels that are the other portions. As described above, the capacitive traces 22 that are the low resistance portions are separated from the channels 17d and 26d that are the other portions. Therefore, the hydrogen diffused from the second interlayer insulating film 34 into the capacitive traces 22 that are the low resistance portions is less likely to affect the channels 17d and 26d that are the other portions. According to the configuration, the electrical resistances of the capacitive traces 22 that are the low resistance portions and the channels 17d and 26d that are the other portions are properly maintained and thus the capacitive traces 22 and the channels 17d and 26d properly exert the electrical performances.

The pixel electrodes 18 and the capacitive traces 22 are provided. The pixel electrodes 18 are formed from the transparent electrode film 35 and in the upper layer relative to the second interlayer insulating film 34. The capacitive traces 22 are formed in the lower layer relative to the first interlayer insulating film 33 to overlap the pixel electrodes 18. The low resistance portions of the oxide semiconductor film 31 are configured as the capacitive traces 22. Because the capacitive traces 22 are arranged to overlap the pixel electrodes 18, the capacitances are held between the pixel electrodes 18 and the capacitive traces 22. Therefore, the pixel electrodes 18 hold the electrical potential. Because the capacitive traces 22 are the low resistance portions separated from the channel 17d and 26d that are the other portions of the oxide semiconductor film, sufficient capacitances are held between the pixel electrodes 18 and the capacitive traces 22. Furthermore, in comparison to a configuration in which the capacitive traces are formed from a light blocking film such as a metal film, the capacitive traces 22 are less likely to block light. Therefore, the amount of transmitting light through the pixel electrodes 18 formed from the transparent electrode film 35 increases.

The pixel electrodes 18 and the display-side TFTs 17 (the transistors) are provided. The pixel electrodes 18 are formed from the transparent electrode film 35 in the upper layer relative to the second interlayer insulating film 34. The display-side TFTs 17 in the lower layer relative to the pixel electrodes 18 are connected to the pixel electrodes 18 to control the application of the electrical potentials to the pixel electrodes 18. The other portions of the oxide semiconductor film 31 are configured as the channels 17d included in the display-side TFTs 17. According to the configuration, the application of the electrical potentials to the pixel electrodes 18 is controlled by the display-side TFTs 17. The channels 17d of the display-side TFTs 17 are the other portions of the oxide semiconductor film separated from the low resistance portions. Therefore, the display-side TFTs 17 are properly operable.

The method of producing the array board 11b according to this embodiment includes the oxide semiconductor film forming step, the first interlayer insulating film forming step (the first insulting film forming step), the hole forming step, and the second interlayer insulating film forming step (the second insulating film forming step). The oxide semiconductor film forming step is for forming the oxide semiconductor film 31 made of the oxide semiconductor material including the capacitive traces 22 that are the portions of the oxide semiconductor film 31 separated from the channels 17d and 26d that are the other portions of the oxide semiconductor film 31. The first interlayer insulating film forming step is for forming the first interlayer insulating film 33 in the upper layer relative to the oxide semiconductor film 31. The hole forming step is for forming the holes 33a in the first interlayer insulating film 33 at the positions overlapping the capacitive traces 22 that are the portions of the oxide semiconductor film 31. The second interlayer insulating film forming step is for forming the second interlayer insulating film containing hydrogen in the upper layer relative to the first interlayer insulating film 33.

After the oxide semiconductor film forming step and the first interlayer insulating film forming step, the first interlayer insulating film 33 is formed in the upper layer relative to the oxide semiconductor film 31 including the portions that are configured as the capacitive traces 22 separated from the other portions that are configured as the channels 17d and 26d. In the hole forming step, the holes 33a are formed in the first interlayer insulating film 33 at the positions overlapping the capacitive traces 22 that are the portions of the oxide semiconductor film 31. In the second interlayer insulating film forming step performed after the hole forming step, the second interlayer insulating film 34 is formed in the upper layer relative to the first interlayer insulating film 33. The portions of the second interlayer insulating film 34 are directly layered on the capacitive traces 22 that are the portions of the oxide semiconductor film 31 facing the holes 33a in the first interlayer insulating film 33 via the holes 33a. The hydrogen contained in the second interlayer insulating film 34 is diffused into the capacitive traces 22 that are the portions of the oxide semiconductor film 31 facing the holes 33a. As a result, the electrical resistances of the capacitive traces 22 are reduced. Because the electrical resistances of the capacitive traces 22 that are the portions of the oxide semiconductor film 31 are reduced using the second interlayer insulating film 34, the special treatment such as the hydrogen plasma treatment included in the know method is not required. Therefore, the production can be performed at low cost. Furthermore, if the capacitive traces that are the portions of the oxide semiconductor film with the reduced electrical resistances and the channels that are the other portions are connected to one another, the hydrogen diffused from the second interlayer insulating film 34 into the capacitive traces that are the portions of the oxide semiconductor film may be diffused into the channels that are the other portions. As described above, the capacitive traces 22 that are the portions of the oxide semiconductor film 31 are separated from the channels 17d and 26d that are the other portions. Therefore, the hydrogen diffused into the capacitive traces 22 that are the portions of the oxide semiconductor film 31 are less likely to affect the channels 17d and 26d that are the other portions. According to the configuration, the electrical resistances of the capacitive traces 22 that are the portions of the oxide semiconductor film 31 and the channels 17d and 26d that are the other portions of the oxide semiconductor film 31 are properly maintained. Therefore, the oxide semiconductor film 31 and the channels 17d and 26d properly exert the electrical performances.

In the second interlayer insulating film forming step, the second interlayer insulating film 34 is formed at the forming temperature in the range from 220° C. to 270° C. If the forming temperature of the second interlayer insulating film 34 is below 220° C., the hydrogen is not sufficiently diffused into the capacitive traces 22 that are the portions of the oxide semiconductor film 31. Therefore, the electrical resistances of the capacitive traces 22 that are the portions of the oxide semiconductor film 31 are not sufficiently reduced. If the forming temperature of the second interlayer insulating film 34 is above 270° C., the elements contained in the oxide semiconductor film 31 may be diffused into the second interlayer insulating film 34 and the bumps and the dips may be formed on and in the surface of the second interlayer insulating film 34. As described above, the forming temperature of the second interlayer insulating film 34 in the second interlayer insulating film forming step is in the range from 220° C. to 270° C. Therefore, the hydrogen is sufficiently diffused into the capacitive traces 22 that are the portions of the oxide semiconductor film 31 and the electrical resistances of the capacitive traces 22 that are the portions of the oxide semiconductor film 31 are sufficiently reduced. Furthermore, the elements contained in the oxide semiconductor film 31 are less likely to be diffused into the second interlayer insulating film 34 and thus the bumps and the dips are less likely to be formed on and in the surface of the second interlayer insulating film 34.

### Second Embodiment

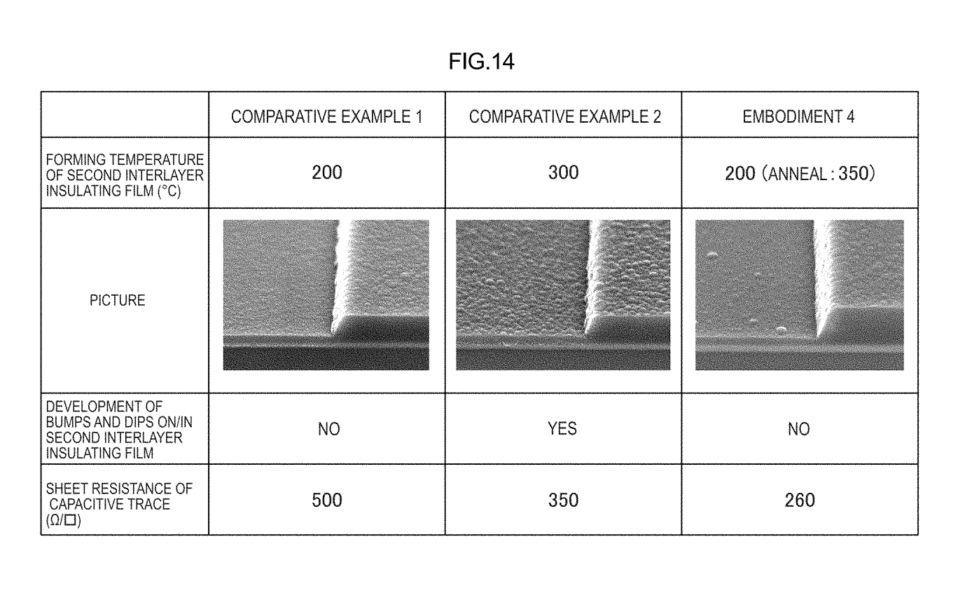

A second embodiment according to the present invention will be described with reference to FIG. 14. The second embodiment includes an annealing treatment step performed after the second interlayer insulating film forming step. Similar configurations, operations, and effects to the first embodiment described above will not be described.

In the method of producing the array board according to this embodiment, the second interlayer insulating film forming step is performed with a lower forming temperature in comparison to the first embodiment. The annealing treatment step is performed after the second interlayer insulating film forming step for performing the annealing treatment under a temperature environment higher than the forming temperature in the second interlayer insulating film forming step. In this embodiment, the second interlayer insulating film forming step is performed with the forming temperature in a range from 150° C. to 220° C. (e.g., 200° C.) and the annealing treatment is performed with a temperature in a range from 220° C. to 350° C., more preferably, from 270° C. to 350° C. (e.g., 350° C.), for a predefined period in the annealing treatment step performed after the second interlayer insulating film forming step. The annealing treatment is performed under an air environment (non-vacuum environment).

Comparative experiment 2 was conducted to examine the electrical resistances of the capacitive traces formed from the oxide semiconductor film and the development of the bumps and dips on and in the surface of the second interlayer insulating film through the method of producing the array board according to this embodiment. In embodiment 4 in comparative experiment 2, the forming temperature of the second interlayer insulating film was set to 200° C. in the second interlayer insulating film forming step and the annealing treatment temperature was set to 350° C. in the annealing treatment step. In embodiment 4, the treatment period was set to two hours in the annealing treatment step. The results of comparative experiment 2 are illustrated in FIG. 14. In FIG. 14, comparative examples 1 and 2 in the comparative experiment 1 described in the first embodiment section are present as comparative samples. FIG. 14 illustrates a table including pictures of surfaces of the second interlayer insulating films in comparative examples 1 and 2 and embodiment 4 captured by the SEM, determination of development of the bumps and dips, and the sheet resistances of the capacitive traces.

The results of comparative experiment 2 will be described. In embodiment 4, the bumps and the dips were not formed on and in the surface of the interlayer insulating film. Furthermore, the sheet resistance of the capacitive trace was 260Ω/□. The electrical resistance of the capacitive trace was sufficiently reduced. Specifically, in embodiment 4, the second interlayer insulating film was formed at the forming temperature of 200° C., which was lower than 220° C., in the second interlayer insulating film forming step. Therefore, the elements such as zinc included in the oxide semiconductor film were less likely to be diffused into the second interlayer insulating film and thus the bumps and the dips were less likely to be formed on and in the surface of the second interlayer insulting film. At the completion of the second interlayer insulating film forming step, the hydrogen contained in the second interlayer insulating film was not sufficiently diffused into the capacitive traces formed from the oxide semiconductor film. Therefore, the electrical resistance of the capacitive trace formed from the oxide semiconductor film may not be sufficiently reduced. In embodiment 4, the annealing treatment step was performed after the second interlayer insulating film forming step. In the annealing treatment step, the annealing treatment was performed at 350° C. or higher and 220° C. or higher. Therefore, the hydrogen contained in the second interlayer insulating film was sufficiently diffused into the capacitive traces formed from the oxide semiconductor film. According to the configuration, the electrical resistance of the capacitive trace formed from the oxide semiconductor film was sufficiently reduced. The bumps and the dips may be formed on and in the surface of the second interlayer insulating film when the second interlayer insulating film is formed in the upper layer relative to the first interlayer insulating film. Therefore, if the annealing treatment is performed with the temperature of 270° C. or higher after the formation of the second interlayer insulating film, the bumps and dips are less likely to be newly formed on and in the surface of the second interlayer insulating film.

As described above, the method of producing the array board according to this embodiment includes the second interlayer insulating film forming step in which the second interlayer insulating film is formed at the forming temperature in the range from 150° C. to 220° C. and the annealing treatment step in which the annealing treatment is performed with the temperature in the range from 220° C. to 350° C. after the second interlayer insulating film forming step. If the second interlayer insulating film is formed at the forming temperature lower than 220° C. in the second interlayer insulating film forming step, the elements contained in the oxide semiconductor film are less likely to be diffused into the second interlayer insulating film and thus the bumps and the dips are less likely to be formed on and in the surface of the second interlayer insulating film. However, the hydrogen may not be sufficiently diffused into the capacitive traces that are the portions of the oxide semiconductor film and thus the electrical resistances of the capacitive traces that are the portions of the oxide semiconductor film may not be sufficiently reduced. In the annealing treatment step performed after the second interlayer insulating film forming step, the annealing treatment is performed with the temperature of 220° C. or higher. Therefore, the hydrogen is sufficiently diffused into the capacitive traces that are the portions of the oxide semiconductor film and thus the electrical resistances of the capacitive traces that are the portions of the oxide semiconductor film are sufficiently reduced. If the second interlayer insulating film is formed at the forming temperature of 150° C. or lower in the second interlayer insulating film forming step or the annealing treatment is performed with the temperature of 350° C. or higher in the annealing treatment step, the display-side TFTs on the array board may not properly exert the electrical performances. As described above, by setting the forming temperature of the second interlayer insulating film to 150° C. or higher in the second interlayer insulating film forming step and the temperature of the annealing treatment to 350° C. or lower in the annealing treatment step, the display-side TFTs on the array board can be properly exert the electrical performances.

In the annealing treatment step, the annealing treatment is performed with the temperature in the range from 270° C. to 350° C. The electrical resistances of the capacitive traces that are the portions of the oxide semiconductor film are more properly reduced. The bumps and the dips may be formed on and in the surface of the second interlayer insulating film when the second interlayer insulating film is formed in the upper layer relative to the first interlayer insulating film. By performing the annealing treatment with the temperature in the range from 270° C. to 350° C. after the formation of the second interlayer insulating film, the bumps and the dips are less likely to be newly formed on and in the surface of the second interlayer insulating film.

### Third Embodiment

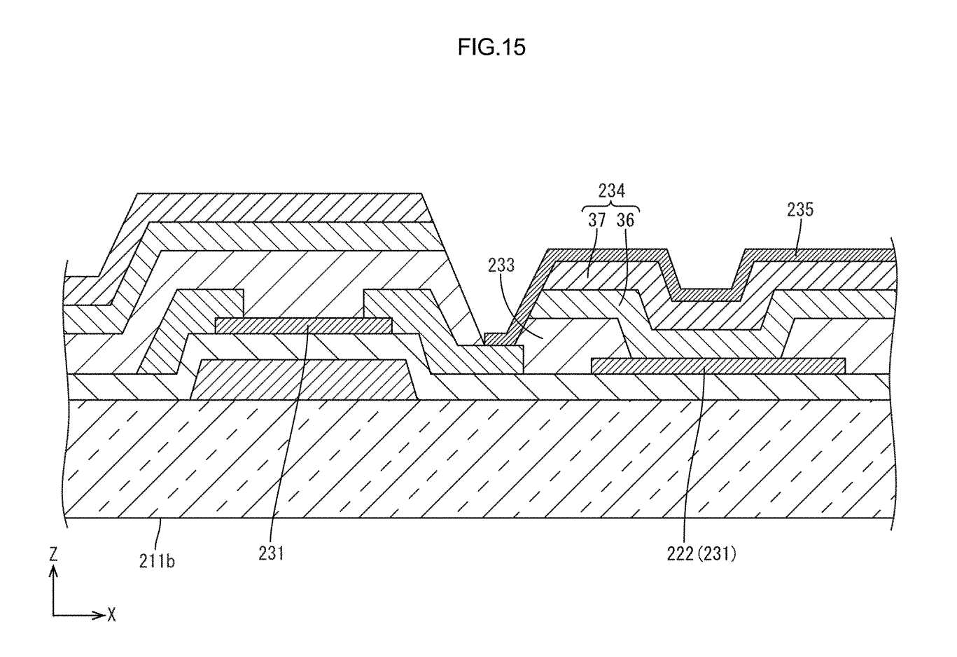

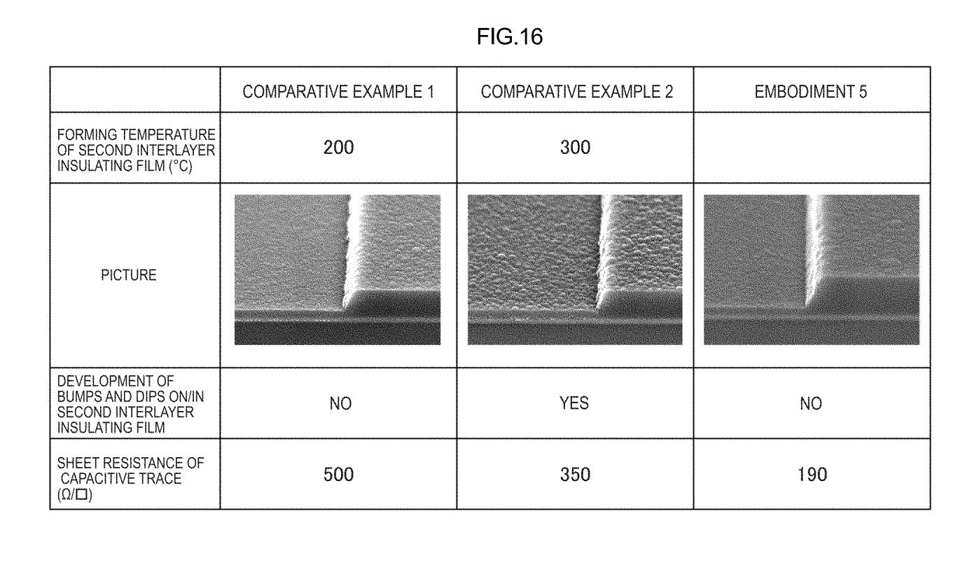

A third embodiment according to the present invention will be described with reference to FIGS. 15 and 16. The third embodiment includes a second interlayer insulating film 234 having a double layer structure, which is different from the first embodiment. Similar configurations, operations, and effects to the first embodiment will not be described.

As illustrated in FIG. 15, the second interlayer insulating film 234 according to this embodiment includes a lower second interlayer insulating film 36 and an upper second interlayer insulating film 37 formed in layers. The lower second interlayer insulating film 36 is formed in a lower layer and the upper second interlayer insulating film 37 is formed in an upper layer. The lower second interlayer insulating film 36 is formed in a lower layer relative to a first interlayer insulating film 233. The upper second interlayer insulating film 37 is formed in a lower layer relative to a transparent electrode film 235. The lower second interlayer insulating film 36 and the upper second interlayer insulating film 37 are made from the same material, that is, silicon nitride (SiNx).

A method of producing an array board 211b according to this embodiment includes a second interlayer insulating film forming step. The second interlayer insulating film forming step includes a lower second interlayer insulating film forming step and an upper second interlayer insulating film forming step. The lower second interlayer insulating film forming step is for forming the lower second interlayer insulating film 36 at a lower forming temperature. The upper second interlayer insulating film forming step is for forming the upper second interlayer insulating film 37 at a higher forming temperature. A preferable forming temperature in the lower second interlayer insulating film forming step is in a range from 150° C. to 270° C. A specific preferable forming temperature is about 200° C. A preferable forming temperature in the upper second interlayer insulating film forming step is in a range from 220° C. to 350° C. A specific preferable forming temperature is about 300° C.

Comparative experiment 3 was conducted to examine the electrical resistances of the capacitive traces 222 formed from an oxide semiconductor film 231 and the development of the bumps and the dips on and in the surface of the second interlayer insulating film 234 with the method of producing the array board 211b according to this embodiment. In embodiment 5 in comparative experiment 3, the forming temperature of the lower second interlayer insulating film 36 was set to 200° C. in the lower second interlayer insulating film forming step and the upper second interlayer insulating film 37 was set to 200° C. in the upper second interlayer insulating film forming step. The results of comparative experiment 3 are illustrated in FIG. 16. In FIG. 16, comparative examples 1 and 2 in the comparative experiment 1 described in the first embodiment section are present as comparative samples. FIG. 16 illustrates a table including pictures of surfaces of the second interlayer insulating films in comparative examples 1 and 2 and embodiment 5 captured by the SEM, the development of the bumps and the dips, and the sheet resistances of the capacitive traces.

The results of comparative experiment 3 will be described. In embodiment 5, the bumps and the dips were not formed on and in the surface of the second interlayer insulating film 234. Furthermore, the sheet resistance of the capacitive trace 222 was 190Ω/□. The electrical resistance of the capacitive trace 222 was lower in comparison to the first and the second embodiments. Specifically, in embodiment 5, the lower second interlayer insulating film 36 was formed at the forming temperature of 200° C., which was lower than 220° C., in the lower second interlayer insulating film forming step. Therefore, the elements included in the oxide semiconductor film such as zinc were less likely to be diffused into the second interlayer insulating film and thus the bumps and the dips were less likely to be formed on and in the surface of the second interlayer insulting film. At the completion of the lower second interlayer insulating film forming step, the hydrogen contained in the lower second interlayer insulating film 36 was not sufficiently diffused into the capacitive traces formed from the oxide semiconductor film. Therefore, the electrical resistance of the capacitive trace 222 formed from the oxide semiconductor film 231 may not be sufficiently reduced. In embodiment 5, the upper second interlayer insulating film forming step was performed after the lower second interlayer insulating film forming step with the higher forming temperature. Therefore, the hydrogen contained in the lower second interlayer insulating film 36 was sufficiently diffused into the capacitive traces 222 formed from the oxide semiconductor film 231 under such a temperature environment. According to the configuration, the electrical resistance of the capacitive trace 222 formed from the oxide semiconductor film 231 was sufficiently reduced. Although the upper second interlayer insulating film 37 is formed under the high temperature environment of 300° C., the elements contained in the oxide semiconductor film 231 such as zinc are less likely to reach the upper second interlayer insulating film 37 because the lower second interlayer insulating film 36 is provided between the upper second interlayer insulating film 37 and the oxide semiconductor film 231. Therefore, the bumps and the dips are less likely to be formed on and in the surface of the upper interlayer insulating film 37.

As described above, the second interlayer insulating film 234 included in the array board 211b according to this embodiment includes the lower second interlayer insulating film 36 in the lower layer and the upper interlayer insulating film 37 in the upper layer. If the forming temperature at which the second interlayer insulating film 234 is formed is too low, the hydrogen is not sufficiently diffused into the capacitive traces 222 that are portions of the oxide semiconductor film 231. Therefore, the resistances of the capacitive traces 222 that are the portions of the oxide semiconductor film 231 are not sufficiently reduced. If the forming temperature at which the second interlayer insulating film 234 is too high, the elements contained in the oxide semiconductor film 231 are diffused into the second interlayer insulating film 234. Therefore, the bumps and the dips are more likely to be formed on and in the surface of the second interlayer insulating film 234. As described above, the second interlayer insulating film 234 has a laminated structure including the lower second interlayer insulating film 36 and the upper second interlayer insulating film 37. The lower second interlayer insulating film 36 may be formed at the lower forming temperature and the upper second interlayer insulating film 37 may be formed at the higher forming temperature. According to the configuration, even if the resistance of the oxide semiconductor film 231 is not sufficiently reduced at the completion of the formation of the lower second interlayer insulating film 36, the bumps and the dips are less likely to be formed on and in the surface of the lower second interlayer insulating film 36. The upper second interlayer insulating film 37 is formed at the higher forming temperature. Under such a temperature environment, the hydrogen is efficiently diffused from the lower second interlayer insulating film 36 to the oxide semiconductor film 231 and thus the resistance is reduced. Because the lower second interlayer insulating film 36 is provided between the upper second interlayer insulating film 37 and the oxide semiconductor film 231, the bumps and the dips are less likely to be formed on and in the surface of the upper second interlayer insulating film 37.

The second interlayer insulating film forming step included in the method of producing the array board 211b according to this embodiment includes the lower second insulating film forming step and the upper second interlayer insulating film forming step. The lower second interlayer insulating film forming step is for forming the lower second interlayer insulating film 36 in the lower layer with at the lower forming temperature. The upper second interlayer insulating film forming step is for forming the upper second interlayer insulating film 37 in the upper layer with the higher forming temperature. In the lower second interlayer insulating film forming step, the lower second interlayer insulating film 36 is formed at the lower forming temperature. Even if the resistance of the oxide semiconductor film 231 is not sufficiently reduced, the bumps and the dips are less likely to be formed on and in the surface of the lower second interlayer insulating film 36. In the upper second interlayer insulating film forming step, the upper second interlayer insulating film 37 is formed at the higher forming temperature. Under such a temperature environment, the hydrogen is efficiently diffused from the lower second interlayer insulating film 36 into the oxide semiconductor film 231 and thus the resistance is reduced. Because the lower second interlayer insulating film 36 is provided between the upper second interlayer insulating film 37 and the oxide semiconductor film 231, the bumps and the dips are less likely to be formed on and in the surface of the upper second interlayer insulating film 37.

In the lower second interlayer insulating film forming step, the lower second interlayer insulating film 36 is formed at the forming temperature in the range from 150° C. to 270° C. In the upper second interlayer insulating film forming step, the upper second interlayer insulating film 37 is formed at the forming temperature in the range from 220° C. to 350° C. In the lower second interlayer insulating film forming step, the lower second interlayer insulating film 36 is formed at the forming temperature lower than the forming temperature of the upper second interlayer insulating film 37 and equal to or lower than 270° C. According to the step, the bumps and the dips are further less likely to be formed on and in the surface of the lower second interlayer insulating film 36. In the upper second interlayer insulating film forming step, the lower second interlayer insulating film 36 is formed at the forming temperature higher than the forming temperature of the lower second interlayer insulating film 36 and equal to or higher than 220° C. According to the step, the resistances of the capacitive traces 222 that are the portions of the oxide semiconductor film 231 are further properly reduced. If the lower second interlayer insulating film is formed at the forming temperature of 150° C. in the lower second interlayer insulating film forming step or the upper second interlayer insulating film is formed at the forming temperature of 350° C. in the upper second interlayer insulating film forming step, the display-side TFTs on the array board may not properly exert the electrical performances. By setting the forming temperature of the lower second interlayer insulating film 36 to 150° C. or higher in the lower second interlayer insulating film forming step and setting the forming temperature of the higher second interlayer insulating film 37 to 350° C. or lower in the upper second interlayer insulating film forming step, the display-side TFTs on the array board 211b can properly exert the electrical performances.

In the lower second interlayer insulating film forming step and the upper second interlayer insulating film forming step, the same material is used for the lower second interlayer insulating film 36 and the upper second interlayer insulating film 37. According to the configuration, material cost of the second interlayer insulating film 234 can be reduced.

### Other Embodiments

The present invention is not limited to the embodiments described above and illustrated by the drawings. For example, the following embodiments will be included in the technical scope of the present invention.

(1) In comparative experiment 1 in the first embodiment, embodiments 1 to 3 including the second interlayer insulating films formed at the forming temperatures of 220° C., 250° C., and 270° C. in the second interlayer insulating film forming steps, respectively. However, the forming temperatures of the second interlayer insulating films can be altered to any temperatures within the range from 220° C. to 270° C.

(2) In comparative experiment 2 in the second embodiment, embodiment 4 was used. Embodiment 4 included the second interlayer insulating film formed at the forming temperature of 200° C. in the second interlayer insulating film forming step and treated with the annealing treatment at 350° C. in the annealing treatment step. However, the forming temperature of the second interlayer insulating film may be altered to any temperature within the range from 150° C. to 220° C. Furthermore, the temperature of the annealing treatment may be altered to any temperature within the range from 220° C. to 350° C. The temperature of the annealing treatment is preferably 270° C. or higher. The period of the annealing treatment step can be longer than 2 hours or shorter than 2 hours.

(3) In comparative experiment 3 in the third embodiment, embodiment 5 was used. Embodiment 5 included the lower second interlayer insulating film formed at the forming temperature of 200° C. in the lower second interlayer insulating film forming step and the upper second interlayer insulating film formed at the forming temperature of 300° C. However, the forming temperature of the lower second interlayer insulating film in the lower second interlayer insulating film forming step may be altered to any temperature within the range from 150° C. to 270° C. Furthermore, the forming temperature of the upper second interlayer insulating film in the upper second interlayer insulating film forming step may be altered to any temperature within the range from 220° C. to 350° C.

(4) In each of the above embodiments, the second interlayer insulating film is made of silicon nitride containing hydrogen. However, inorganic materials containing hydrogen other than silicon nitride may be used for the second interlayer insulating film.

(5) In the third embodiment, the lower second interlayer insulating film and the upper second interlayer insulating film are made of the same material. However, composition of material for the lower second interlayer insulating film and composition of material for the upper second interlayer insulating film may be different from each other. It is preferable that the lower second interlayer insulating film and the upper second interlayer insulating film contain hydrogen (especially the lower second interlayer insulating film directly layered on the capacitive traces in the upper layer).

(6) Each of the above embodiments includes the array board including the capacitive traces parallel to the source races. However, the present invention may be applied to an array board including capacitive traces parallel to gate traces. The arrangement, the number, and the two-dimensional shape of the capacitive traces may be altered as appropriate.

(7) Each of the above embodiments includes the oxide semiconductor film made of the In—Ga—Zn—O based oxide semiconductor. However, other oxide semiconductors may be used. For example, a Zn—O based semiconductor (ZnO), an In—Zn—O based semiconductor (IZO (registered trademark)), Zn—Ti—O based semiconductor (ZTO), a Cd—Ge—O based semiconductor, a Cd—Pb—O based semiconductor, a CdO (cadmium oxide), Mg—Zn—O based semiconductor, an In—Sn—Zn—O based semiconductor (e.g., In2O3-SnO2-ZnO), and an In—Ga—Sn—O based semiconductor may be included.

(8) The materials for the films formed in layers on the array board may be altered from the materials used in each of the above embodiments.

(9) In each of the above embodiments, the liquid crystal panel that operates in vertical alignment (VA) mode. However, the present invention may be applied to a liquid crystal panel that operates in in-plane switching (IPS) mode or fringe field switching (FFS) mode.

(10) In each of the above embodiments, the display-side TFTs (the transistors) are used as switching components of the array board. However, the present invention may be applied to an array board including switching components other than the display-side TFTs (the transistors) (e.g., thigh film diodes (TFDs)). Furthermore, the present invention may be applied to a liquid crystal display device for displaying black-and-white images other than the liquid crystal display device for displaying color images.

(11) In each of the above embodiments, the column control circuit and the row control circuit are arranged on the array board in the non-display area. However, any one of or both of the column control circuit and the row control circuit may be omitted and the functions of the control circuits may be performed by the driver. Alternatively, the non-display-side TFTs may be omitted.

(12) In each of the above embodiments, the driver is directly mounted on the array board through the COG mounting. However, a configuration in which a driver is mounted on a flexible circuit board connected to an array board via an ACF may be included in the scope of the present invention.

(13) In each of the above embodiment sections, the transmissive-type liquid crystal display device including the backlight unit, which is an external light source, was described. However, the present invention may be applied to a reflective-type liquid crystal display device configured to display an image using ambient light or a semitransmissive liquid crystal display device. The reflective-type liquid crystal display device may not include a backlight unit.

(14) In each of the above embodiment sections, the array board of the liquid crystal panel was described. However, the present invention may be applied to display panels including a plasma display panel (PDP) and an organic EL panels.

### EXPLANATION OF SYMBOLS

11b, 211b: array board (semiconductor device), 17: display-side TFT (transistor), 17d: channel (another portion), 18: pixel electrode, 22, 222: capacitive line (a portion, low resistance portion), 31, 231: oxide semiconductor film, 33, 233: first interlayer insulating film (first insulating film), 33a: opening, 34, 234: second interlayer insulating film (second insulating film), 35, 235: transparent electrode film, 36: lower second interlayer insulating film (lower second insulating film), 37: upper second interlayer insulating film (upper second insulating film)

1: A semiconductor device comprising:
an oxide semiconductor film made of oxide semiconductor material, the oxide semiconductor film including a low resistance portion having an electrical resistance lower than an electrical resistance of another portion, the low resistance portion being separated from the other portion;
a first insulating film formed in an upper layer relative to the oxide semiconductor film, the first insulating film including a hole at a position overlapping the low resistance portion; and
a second insulating film formed in an upper layer relative to the first insulating film, the second insulating film containing hydrogen.

2: The semiconductor device according to claim 1, further comprising:
a pixel electrode formed from a transparent electrode film in an upper layer relative to the second insulating film; and
a capacitive trace formed in a lower layer relative to the first insulating film to overlap the pixel electrode, wherein
the oxide semiconductor film is formed such that the capacitive trace is formed from the low resistance portion.

3: The semiconductor device according to claim 1, further comprising:
a pixel electrode formed from a transparent electrode film in an upper layer relative to the second insulating film; and
a transistor formed in a lower layer relative to the pixel electrode and connected to the pixel electrode to control application of an electrical potential to the pixel electrode, wherein
the oxide semiconductor film is formed such that a channel included in the transistor is formed from the other portion.

4: The semiconductor device according to claim 1, wherein the second insulating film includes a lower second insulating film formed in a lower layer and an upper second insulating film formed in an upper layer.

5: A method of producing a semiconductor device, the method comprising:
an oxide semiconductor film forming step for forming an oxide semiconductor film from oxide semiconductor material to separate a portion of the oxide semiconductor film from another portion of the oxide semiconductor film;
a first insulating film forming step for forming a first insulating film in an upper layer relative to the oxide semiconductor film;
a hole forming step for forming a hole in the first insulating film at a position overlapping the portion of the oxide semiconductor film; and
a second insulating film forming step for forming a second insulating film containing hydrogen in an upper layer relative to the first insulating film.

6: The method according to claim 5, wherein the second insulating film forming step includes forming the second insulating film at a forming temperature in a range from 220° C. to 270° C.

7: The method according to claim 5, further comprising an annealing treatment step for performing an annealing treatment at a temperature in a range from 220° C. to 350° C. after the second insulating film forming step, wherein
the second insulating film forming step includes forming the second insulating film at a forming temperature in a range from 150° C. to 220° C.

8: The method according to claim 7, wherein the annealing treatment step includes performing the annealing treatment at a temperature in a range from 270° C. to 350° C.

9: The method according to claim 5, wherein the second insulating film forming step comprises:
a lower second insulating film forming step for forming a lower second insulating film in a lower layer at a lower forming temperature; and
an upper second insulating film forming step for forming an upper second insulating film in an upper layer at a higher forming temperature.

10: The method according to claim 9, wherein
the lower second insulating film forming step includes forming the lower second insulating film at a forming temperature in a range from 150° C. to 270° C., and
the upper second insulating film forming step includes forming the upper second insulating film at a forming temperature in a range from 220° C. to 350° C.

11: The method according to claim 9, wherein a material used for forming the lower second insulating film in the lower second insulating film forming step and a material used for forming the upper second insulating film in the upper second insulating film forming step are the same.
